(19) United States
(12) Patent Application Publication
(10) Pub. No.: US 2009/0205968 A1
(43) Pub. Date: Aug. 20, 2009

(54) ORGANOMETALLIC COMPOUNDS, PROCESSES FOR THE PREPARATION THEREOF AND METHODS OF USE THEREOF

(76) Inventors: David M. Thompson, East Amherst, NY (US); Joan Geary, Lakeview, NY (US); Adrien R. Lavoie, St. Helens, OR (US); Juan E. Dominquez, Hillsboro, OR (US)

Correspondence Address: PRAXAIR, INC.;LAW DEPARTMENT - M1 557, 39 OLD RIDGEBURY ROAD, DANBURY, CT, 06810-5113, US

(21) Appl. No.: 12/352,269

(22) Filed: Jan. 12, 2009

Related U.S. Application Data
(60) Provisional application No. 61/023,131, filed on Jan. 24, 2008.
(60) Provisional application No. 61/023,125, filed on Jan. 24, 2008.
(60) Provisional application No. 61/023,136, filed on Jan. 24, 2008.

(51) Int. Cl. C23C 28/00; C23C 16/00; H05H 1/24

(52) U.S. Cl. 205/183; 427/126.1; 427/576

(57) ABSTRACT

This invention relates to organometallic compounds having the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0; a process for producing the organometallic compounds, and a method for producing a film or coating from the organometallic compounds. The organometallic compounds are useful in semiconductor applications as chemical vapor or atomic layer deposition precursors for film depositions.

### RELATED APPLICATIONS

This application claims priority from provisional U.S. Patent Application Ser. No. 61/023,131, filed Jan. 24, 2008, which is incorporated herein by reference. This application is related to U.S. Patent Application Ser. No. (21699-R1), filed on an even date herewith, U.S. Patent Application Ser. No. (21699-R2), filed on an even date herewith, U.S. Patent Application Ser. No. (21646-R1), filed on an even date herewith, U.S. Patent Application Ser. No. (21646-R2), filed on an even date herewith, U.S. Patent Application Ser. No. (21646-R3), filed on an even date herewith, U.S. Patent Application Ser. No. (21700-R1), filed on an even date herewith, U.S. Patent Application Ser. No. (21700-R2), filed on an even date herewith, U.S. Patent Application Ser. No. (21700-R3), filed on an even date herewith, U.S. Patent Application Ser. No. 61/023,125, filed Jan. 24, 2008, and U.S. Patent Application Ser. No. 61/023,136, filed Jan. 24, 2008, all of which are incorporated herein by reference.

### FIELD OF THE INVENTION

This invention relates to organometallic compounds, a process for producing organometallic compounds, and a method for producing a film or coating from organometallic precursor compounds.

### BACKGROUND OF THE INVENTION

The semiconductor industry is currently considering the use of thin films of various metals for a variety of applications. Many organometallic complexes have been evaluated as potential precursors for the formation of these thin films. A need exists in the industry for developing new compounds and for exploring their potential as precursors for film depositions. The industry movement from physical vapor deposition (PVD) to chemical vapor deposition (CVD) and atomic layer deposition (ALD) processes, due to the increased demand for higher uniformity and conformality in thin films, has lead to a demand for suitable precursors for future semiconductor materials.

Many organometallic complexes have been evaluated as potential precursors for the formation of these thin films. These include, for example, carbonyl complexes such as Ru₃(CO)₁₂, diene complexes such as Ru(η³-C₆H₈)(CO)₃, Ru(η³-C₆H₈)(η⁶-C₆H₆), beta-diketonates such as Ru(DPM)₃, Ru(OD)₃ and ruthenocenes such as RuCp₂, Ru(EtCp)₂.

Both the carbonyl and diene complexes tend to exhibit low thermal stabilities which complicates their processing. While the beta-diketonates are thermally stable at moderate temperatures, their low vapor pressures married with their solid state at room temperature make it difficult to achieve high growth rates during film deposition.

Ruthenocenes have received considerable attention as precursors for Ru thin film deposition. While ruthenocene is a solid, the functionalization of the two cyclopentadienyl ligands with ethyl substituents yields a liquid precursor that shares the chemical characteristics of the parent ruthenocene. Unfortunately, depositions with this precursor have generally exhibited long incubation times and poor nucleation densities.

The ability to deposit conformal metal layers in high aspect ratio features by the dissociation of organometallic precursors has gained interest in recent years due to the development of chemical vapor deposition (CVD) techniques. In such techniques, an organometallic precursor comprising a metal component and organic component is introduced into a processing chamber and dissociates to deposit the metal component on a substrate while the organic portion of the precursor is exhausted from the chamber.

There are few commercially available organometallic precursors for the deposition of metal layers, such as ruthenium precursors by CVD techniques. The precursors that are available produce layers which may have unacceptable levels of contaminants such as carbon and oxygen, and may have less than desirable diffusion resistance, low thermal stability, and undesirable layer characteristics. Further, in some cases, the available precursors used to deposit metal layers produce layers with high resistivity, and in some cases, produce layers that are insulative.

Atomic layer deposition (ALD) is considered a superior technology for depositing thin films. However, the challenge for ALD technology is availability of suitable precursors. ALD deposition process involves a sequence of steps. The steps include 1) adsorption of precursors on the surface of substrate; 2) purging off excess precursor molecules in gas phase; 3) introducing reactants to react with precursor on the substrate surface; and 4) purging off excess reactant.

For ALD processes, the precursor should meet stringent requirements. First, the ALD precursors should be able to form a monolayer on the substrate surface either through physisorption or chemisorption under the deposition conditions. Second, the adsorbed precursor should be stable enough to prevent premature decomposition on the surface to result in high impurity levels. Third, the adsorbed molecule should be reactive enough to interact with reactants to leave a pure phase of the desirable material on the surface at relatively low temperature.

As with CVD, there are few commercially available organometallic precursors for the deposition of metal layers, such as ruthenium precursors by ALD techniques. ALD precursors that are available may have one or more of following disadvantages: 1) low vapor pressure, 2) wrong phase of the deposited material, and 3) high carbon incorporation in the film.

In developing methods for forming thin films by chemical vapor deposition or atomic layer deposition methods, a need continues to exist for precursors that preferably are liquid at room temperature, have adequate vapor pressure, have appropriate thermal stability (i.e., for chemical vapor deposition will decompose on the heated substrate but not during delivery, and for atomic layer deposition will not decompose thermally but will react when exposed to co-reactant), can form uniform films, and will leave behind very little, if any, undesired impurities (e.g., halides, carbon, etc.). Therefore, a need continues to exist for developing new compounds and for exploring their potential as chemical vapor or atomic layer deposition precursors for film depositions. It would therefore be desirable in the art to provide a precursor that possesses some, or preferably all, of the above characteristics.

### SUMMARY OF THE INVENTION

This invention relates in part to compounds represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0. Typically, M is selected from ruthenium (Ru), iron (Fe) or osmium (Os), L₁ is selected from substituted or unsubstituted anionic 6 electron donor ligands such as a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, a substituted or unsubstituted pyrazolyl-like group, a substituted or unsubstituted boratabenzene group, and a substituted or unsubstituted boratabenzene-like group, and L₂ is selected from (i) substituted or unsubstituted anionic 2 electron donor ligands such as hydrido, halo and an alkyl group having from 1 to 12 carbon atoms (e.g., methyl, ethyl and the like), (ii) substituted or unsubstituted anionic 4 electron donor ligands such as allyl, azaallyl, amidinate and betadiketiminate, (iii) substituted or unsubstituted neutral 2 electron donor ligands such as carbonyl, phosphino, amino, alkenyl, alkynyl, nitrile (e.g., acetonitrile) and isonitrile, and (iv) substituted or unsubstituted anionic 4 electron donor ligands with a pendant neutral 2 electron donor moiety such as an amidinate with a N-substituted beta or gamma pendant amine.

This invention also relates in part to compounds represented by the formula (L₁)M(L₃)(L₄) wherein M is a metal or metalloid having a (+2) oxidation state, L₁ is a substituted or unsubstituted anionic 6 electron donor ligand, L₃ is a substituted or unsubstituted neutral 2 electron donor ligand, and L₄ is a substituted or unsubstituted anionic 4 electron donor ligand. Typically, M is selected from ruthenium (Ru), iron (Fe) or osmium (Os), L₁ is selected from substituted or unsubstituted anionic 6 electron donor ligands such as a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, a substituted or unsubstituted pyrazolyl-like group, a substituted or unsubstituted boratabenzene group, and a substituted or unsubstituted boratabenzene-like group, L₃ is selected from substituted or unsubstituted neutral 2 electron donor ligands such as carbonyls, phosphines, amines, nitriles, and alkenes, and L₄ is selected from substituted or unsubstituted anionic 4 electron donor ligands such as allyl, azaallyl, amidinate and betadiketiminate.

This invention further relates in part to compounds represented by the formula (L₁)M(L₄)(L₅)₂ wherein M is a metal or metalloid having a (+4) oxidation state, L₁ is a substituted or unsubstituted anionic 6 electron donor ligand, L₄ is a substituted or unsubstituted anionic 4 electron donor ligand, and L₅ is the same or different and is a substituted or unsubstituted anionic 2 electron donor ligand. Typically, M is selected from ruthenium (Ru), iron (Fe) or osmium (Os), L₁ is selected from substituted or unsubstituted anionic 6 electron donor ligands such as a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, a substituted or unsubstituted pyrazolyl-like group, a substituted or unsubstituted boratabenzene group, and a substituted or unsubstituted boratabenzene-like group, L₄ is selected from substituted or unsubstituted anionic 4 electron donor ligands such as allyl, azaallyl, amidinate and betadiketiminate, and L₅ is selected from substituted or unsubstituted anionic 2 electron donor ligands such as hydrido, halo and an alkyl group having from 1 to 12 carbon atoms (e.g., methyl, ethyl and the like).

This invention yet further relates in part to compounds represented by the formula (L₁)M(L₃)₂(L₅) wherein M is a metal or metalloid having a (+2) oxidation state, L₁ is a substituted or unsubstituted anionic 6 electron donor ligand, L₃ is the same or different and is a substituted or unsubstituted neutral 2 electron donor ligand, and L₅ is a substituted or unsubstituted anionic 2 electron donor ligand. Typically, M is selected from ruthenium (Ru), iron (Fe) or osmium (Os), L₁ is selected from substituted or unsubstituted anionic 6 electron donor ligands such as a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, a substituted or unsubstituted pyrazolyl-like group, a substituted or unsubstituted boratabenzene group, and a substituted or unsubstituted boratabenzene-like group, L₃ is selected from substituted or unsubstituted neutral 2 electron donor ligands such as carbonyl, phosphino, amino, alkenyl, alkynyl, nitrile (e.g., acetonitrile) and isonitrile, and L₅ is selected from substituted or unsubstituted anionic 2 electron donor ligands such as hydrido, halo and an alkyl group having from 1 to 12 carbon atoms (e.g., methyl, ethyl and the like).

This invention also relates in part to compounds represented by the formula (L₁)M(L₆) wherein M is a metal or metalloid having a (+2) oxidation state, L₁ is a substituted or unsubstituted anionic 6 electron donor ligand, and L₆ is a substituted or unsubstituted anionic 4 electron donor ligand with a pendant neutral 2 electron donor moiety. Typically, M is selected from ruthenium (Ru), iron (Fe) or osmium (Os), L₁ is selected from substituted or unsubstituted anionic 6 electron donor ligands such as a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, a substituted or unsubstituted pyrazolyl-like group, a substituted or unsubstituted boratabenzene group, and a substituted or unsubstituted boratabenzene-like group, and L₆ is selected from substituted or unsubstituted anionic 4 electron donor ligands with a pendant neutral 2 electron donor moiety such as an amidinate with a N-substituted beta or gamma pendant amine.

This invention further relates in part to organometallic precursor compounds represented by the formulae above.

This invention yet further relates in part to a process for producing an organometallic compound having the formula (L₁)M(L₃)(L₄) wherein M is a metal or metalloid having a (+2) oxidation state, L₁ is a substituted or unsubstituted anionic 6 electron donor ligand, L₃ is a substituted or unsubstituted neutral 2 electron donor ligand, and L₄ is a substituted or unsubstituted anionic 4 electron donor ligand; which process comprises reacting a metal halide and a first salt in the presence of a first solvent and under reaction conditions sufficient to produce an intermediate reaction material, and reacting said intermediate reaction material with a second salt in the presence of a second solvent and under reaction conditions sufficient to produce said organometallic compound.

This invention also relates in part to a process for producing an organometallic compound having the formula (L₁)M(L₄)(L₅)₂ wherein M is a metal or metalloid having a (+4) oxidation state, L₁ is a substituted or unsubstituted anionic 6 electron donor ligand, L₄ is a substituted or unsubstituted anionic 4 electron donor ligand, and L₅ is the same or different and is a substituted or unsubstituted anionic 2 electron donor ligand; which process comprises reacting a metal halide and a first salt in the presence of a first solvent and under reaction conditions sufficient to produce a first intermediate reaction material, reacting said first intermediate reaction material with a second salt in the presence of a second solvent and under reaction conditions sufficient to produce a second intermediate reaction material, and reacting said second intermediate reaction material with an alkylating agent in the presence of a third solvent and under reaction conditions sufficient to produce said organometallic compound.

This invention further relates in part to a process for producing an organometallic compound having the formula (L₁)M(L₃)₂(L₅) wherein M is a metal or metalloid having a (+2) oxidation state, L₁ is a substituted or unsubstituted anionic 6 electron donor ligand, L₃ is the same or different and is a substituted or unsubstituted neutral 2 electron donor ligand, and L₅ is a substituted or unsubstituted anionic 2 electron donor ligand; which process comprises reacting a metal halide and a salt in the presence of a solvent and under reaction conditions sufficient to produce an intermediate reaction material, and reacting said intermediate reaction material with an alkyl source compound in the presence of a second solvent and under reaction conditions sufficient to produce said organometallic compound.

This invention yet further relates to a process for producing an organometallic compound having the formula (L₁)M(L₆) wherein M is a metal or metalloid having a (+2) oxidation state, L₁ is a substituted or unsubstituted anionic 6 electron donor ligand, and L₆ is a substituted or unsubstituted anionic 4 electron donor ligand with a pendant neutral 2 electron donor moiety; which process comprises reacting a metal halide and a first salt in the presence of a first solvent and under reaction conditions sufficient to produce a first intermediate reaction material, and reacting said first intermediate reaction material with a second salt in the presence of a second solvent and under reaction conditions sufficient to produce a second intermediate reaction material, and heating said second intermediate reaction material to produce said organometallic compound.

This invention also relates to a method for producing a film, coating or powder by decomposing an organometallic precursor compound having the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0; thereby producing said film, coating or powder.

This invention further relates to a method for processing a substrate in a processing chamber, said method comprising (i) introducing an organometallic precursor compound into said processing chamber, (ii) heating said substrate to a temperature of about 100° C. to about 600° C., and (iii) reacting said organometallic precursor compound in the presence of a processing gas to deposit a metal-containing layer on said substrate; wherein said organometallic precursor compound is represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0.

This invention yet further relates to a method for forming a metal-containing material on a substrate from an organometallic precursor compound, said method comprising vaporizing said organometallic precursor compound to form a vapor, and contacting the vapor with the substrate to form said metal material thereon; wherein said organometallic precursor compound is represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0.

This invention also relates in part to a method of fabricating a microelectronic device structure, said method comprising vaporizing an organometallic precursor compound to form a vapor, and contacting said vapor with a substrate to deposit a metal-containing film on the substrate, and thereafter incorporating the metal-containing film into a semiconductor integration scheme; wherein said organometallic precursor compound represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0.

This invention yet further relates in part to mixtures comprising (i) a first organometallic precursor compound represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0, and (ii) one or more different organometallic compounds (e.g., a hafnium-containing, tantalum-containing or molybdenum-containing organometallic precursor compound).

This invention relates in particular to depositions involving 6-electron donor anionic ligand-based ruthenium precursors. These precursors can provide advantages over the other known precursors, especially when utilized in tandem with other ‘next-generation’ materials (e.g., hafnium, tantalum and molybdenum). These ruthenium-containing materials can be used for a variety of purposes such as dielectrics, adhesion layers, diffusion barriers, electrical barriers, and electrodes, and in many cases show improved properties (thermal stability, desired morphology, less diffusion, lower leakage, less charge trapping, and the like) than the non-ruthenium containing films.

The invention has several advantages. For example, the method of the invention is useful in generating organometallic precursor compounds that have varied chemical structures and physical properties. Films generated from the organometallic precursor compounds can be deposited with a short incubation time, and the films deposited from the organometallic precursor compounds exhibit good smoothness. These 6-electron donor anionic ligand-containing ruthenium precursors may be deposited by atomic layer deposition employing a hydrogen reduction pathway in a self-limiting manner, thereby enabling use of ruthenium as a barrier/adhesion layer in conjunction with tantalum nitride in BEOL (back end of line) liner applications. Such 6-electron donor anionic ligand-containing ruthenium precursors deposited in a self-limiting manner by atomic layer deposition may enable conformal film growth over high aspect ratio trench architectures in a reducing environment.

The organometallic precursors of this invention exhibit different bond energies, reactivities, thermal stabilities, and volatilities that better enable meeting integration requirements for a variety of thin film deposition applications. Specific integration requirements include reactivity with reducing process gases, good thermal stability, and moderate volatility. The precursors do not introduce high levels of oxygen into the film. The films obtained from the precursors exhibit acceptable densities for barrier applications.

An economic advantage associated with the organometallic precursors of this invention is their ability to enable technologies that permit continued scaling. Scaling is the primary force responsible for reducing the price of transistors in semiconductors in recent years.

A preferred embodiment of this invention is that the organometallic precursor compounds may be liquid at room temperature. In some situations, liquids may be preferred over solids from an ease of semiconductor process integration perspective. The 6-electron donor anionic ligand-containing ruthenium compounds are preferably hydrogen reducible and deposit in a self-limiting manner.

For CVD and ALD applications, the organometallic precursors of this invention can exhibit an ideal combination of thermal stability, vapor pressure, and reactivity with the intended substrates for semiconductor applications. The organometallic precursors of this invention can desirably exhibit liquid state at delivery temperature, and/or tailored ligand spheres that can lead to better reactivity with semiconductor substrates.

### DETAILED DESCRIPTION OF THE INVENTION

As indicated above, this invention relates to compounds represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0.

Preferably, M is selected from ruthenium (Ru), iron (Fe) or osmium (Os), L₁ is selected from a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, a substituted or unsubstituted pyrazolyl-like group, a substituted or unsubstituted boratabenzene group, and a substituted or unsubstituted boratabenzene-like group, and L₂ is selected from (i) a substituted or unsubstituted hydrido, halo and an alkyl group having from 1 to 12 carbon atoms, (ii) a substituted or unsubstituted allyl, azaallyl, amidinate and betadiketiminate group, (iii) a substituted or unsubstituted carbonyl, phosphino, amino, alkenyl, alkynyl, nitrile and isonitrile group, and (iv) a substituted or unsubstituted anionic 4 electron donor ligand with a pendant neutral 2 electron donor moiety such as an amidinate with a N-substituted beta or gamma pendant amine.

The compounds represented by the formula (L₁)M(L₂)_{y} can be selected from the following: (a) M is ruthenium (Ru) having a (+2) oxidation state, L₁ is a substituted or unsubstituted anionic 6 electron donor ligand with a (−1) electrical charge, L₂ is the same or different and is (i) a substituted or unsubstituted anionic 2 electron donor ligand with a (−1) electrical charge, (ii) a substituted or unsubstituted anionic 4 electron donor ligand with a (−1) electrical charge, (iii) a substituted or unsubstituted neutral 2 electron donor ligand with a zero (0) electrical charge, or (iv) a substituted or unsubstituted anionic 4 electron donor ligand with a pendant neutral 2 electron donor moiety with a (−1) electrical charge; and y is an integer of 2 or 3; and wherein the sum of the oxidation number of M and the electric charges of L₁ and L₂ is equal to 0; and (b) M is ruthenium (Ru) having a (+4) oxidation state, L₁ is a substituted or unsubstituted anionic 6 electron donor ligand with a (−1) electrical charge, L₂ is the same or different and is (i) a substituted or unsubstituted anionic 2 electron donor ligand with a (−1) electrical charge, (ii) a substituted or unsubstituted anionic 4 electron donor ligand with a (−1) electrical charge, or (iii) a substituted or unsubstituted anionic 4 electron donor ligand with a pendant neutral 2 electron donor moiety with a (−1) electrical charge; and y is an integer of 3; and wherein the sum of the oxidation number of M and the electric charges of L₁ and L₂ is equal to 0.

Referring to the compounds represented by the formula (L₁)M(L₂)_{y}, the substituted or unsubstituted cyclopentadienyl-like group is selected from cyclohexadienyl, cycloheptadienyl, cyclooctadienyl, heterocyclic group and aromatic group, the substituted or unsubstituted cycloheptadienyl-like group is selected from cyclohexadienyl, cyclooctadienyl, heterocyclic group and aromatic group, the substituted or unsubstituted pentadienyl-like group is selected from linear olefins, hexadienyl, heptadienyl and octadienyl, the substituted or unsubstituted pyrrolyl-like group is selected from pyrrolinyl, pyrazolyl, thiazolyl, oxazolyl, carbazolyl, triazolyl, indolyl and purinyl, the substituted or unsubstituted imidazoyl-like group is selected from pyrrolinyl, pyrazolyl, thiazolyl, oxazolyl, carbazolyl, triazolyl, indolyl and purinyl, the substituted or unsubstituted pyrazolyl-like group is selected from pyrrolinyl, pyrazolyl, thiazolyl, oxazolyl, carbazolyl, triazolyl, indolyl and purinyl, and the substituted or unsubstituted boratabenzene-like group is selected from methylboratabenzene, ethylboratabenzene, 1-methyl-3-ethylboratabenzene or other functionalized boratabenzene moieties.

Also, referring to the compounds represented by the formula (L₁)M(L₂)_{y}, M preferably can be selected from Ru, Fe and Os. Other illustrative metals or metalloids include, for example, Ti, Zr, Hf, V, Nb, Ta, Cr, Mo, W, Mn, Tc, Re, Co, Rh, Ir, Ni, Pd, Pt, Cu, Ag, Au, Zn, Cd, Hg, Al, Ga, Si, Ge, a Lanthanide series element or an Actinide series element.

Illustrative compounds represented by the formula (L₁)M(L₂)_{y} include, for example, methylboratabenzene(allyl)carbonylruthenium(II), (pyrrolyl)trimethylamino(diisopropylacetamidinato)ruthenium(II), (ethylcyclopentadienyl)allyl(carbonyl)ruthenium(II), cyclopentadienyl(2-methyl-allyl)carbonylruthenium(II), (ethylcyclopentadienyl)(dimethyl)allylruthenium(IV), (2,5-dimethylpyrrolyl)(dimethyl)allylruthenium(IV), allyl(ethylcyclopentadienyl)dimethylruthenium(IV), (methylboratabenzene)dimethyl(diisopropylacetamidinato)ruthenium(IV), (ethylcyclopentadienyl)dicarbonyl(methyl)ruthenium(II), pyrrolyl(dicarbonyl)(methyl)ruthenium(II), methylboratabenzene-di(trimethylphosphino)methylruthenium(II), [ⁱPrNCCH₃N(CH₂)₃N(CH₃)₂](ethylcyclopentadienyl)ruthenium(II), [EtNCCH₃N(CH₂)₂N(CH₃)₂] (cyclopentadienyl)ruthenium(II), [H₂CCHCH(CH₂)₃N(CH₃)₂] (ethylcyclopentadienyl)ruthenium(II), [H₂CCHCH(CH₂)₂(HC═CH₂)](pyrrolyl)ruthenium(II), [ⁱPrNCCH₃N(CH₂)₃N(CH₃)₂](methylboratabenzene)ruthenium(II), methylboratabenzene(allyl)carbonylosmium(II), (pyrrolyl)trimethylamino(diisopropylacetamidinato)iron(II), (ethylcyclopentadienyl)allyl(carbonyl)osmium(II), cyclopentadienyl(2-methyl-allyl)carbonyliron(II), allyl(carbonyl)ethylcyclopentadienyliron(II), (ethylcyclopentadienyl)(dimethyl)allylosmium(IV), (2,5-dimethylpyrrolyl) (dimethyl)allyliron(IV), (methylboratabenzene)dimethyl(diisopropyl-acetamidinato)osmium(IV), allyl(ethylcyclopentadienyl)dimethylosmium(IV), (pyrrolyl)methyl(dicarbonyl)iron(II), (ethylcyclopentadienyl)dicarbonyl(methyl)iron(II), pyrrolyl(dicarbonyl)(methyl)osmium(II), methylboratabenzene-di(trimethylphosphino)methyliron(II), [ⁱPrNCCH₃N(CH₂)₃N(CH₃]₂(ethylcyclop entadienyl)osmium(II), [ⁱPrNCCH₃N(CH₂)₃N(CH₃)₂](methylboratabenzene)osmium(II), [ⁱPrNCCH₃N(CH₂)₃N(CH₃)₂](ethylcyclopentadienyl)iron(II), [EtNCCH₃N(CH₂)₂N(CH₃)₂](cyclopentadienyl)osmium(II), [H₂CCHCH(CH₂)₃N(CH₃)₂](ethylcyclopentadienyl)osmium(II), and [H₂CCHCH(CH₂)₂(HC═CH₂)](pyrrolyl)iron(II). In an embodiment, the organometallic compounds undergo hydrogen reduction.

Other compounds within the scope of this invention can be represented by the formula (L₁)M(L₃)(L₄) wherein M is a metal or metalloid having a (+2) oxidation state, L₁ is a substituted or unsubstituted anionic 6 electron donor ligand, L₃ is a substituted or unsubstituted neutral 2 electron donor ligand, and L₄ is the same or different and is a substituted or unsubstituted anionic 4 electron donor ligand.

Preferably, M is selected from ruthenium (Ru), iron (Fe) or osmium (Os), L₁ is selected from a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, a substituted or unsubstituted pyrazolyl-like group, a substituted or unsubstituted boratabenzene group, and a substituted or unsubstituted boratabenzene-like group, L₃ is selected from a substituted or unsubstituted carbonyl, phosphino, amino, alkenyl, alkynyl, nitrile and isonitrile group, and L₄ is selected from a substituted or unsubstituted allyl, azaallyl, amidinate and betadiketiminate group.

The compounds represented by the formula (L₁)M(L₃)(L₄) can include those compounds where M is ruthenium (Ru) with a (+2) oxidation number, L₁ is a substituted or unsubstituted anionic 6 electron donor ligand with a (−1) electrical charge, L₃ is a substituted or unsubstituted neutral 2 electron donor ligand with a zero (0) electrical charge, and L₄ is a substituted or unsubstituted anionic 4 electron donor ligand with a (−1) electrical charge.

Referring to the compounds represented by the formula (L₁)M(L₃)(L₄), the substituted or unsubstituted cyclopentadienyl-like group is selected from cyclohexadienyl, cycloheptadienyl, cyclooctadienyl, heterocyclic group and aromatic group, the substituted or unsubstituted cycloheptadienyl-like group is selected from cyclohexadienyl, cyclooctadienyl, heterocyclic group and aromatic group, the substituted or unsubstituted pentadienyl-like group is selected from linear olefins, hexadienyl, heptadienyl and octadienyl, the substituted or unsubstituted pyrrolyl-like group is selected from pyrrolinyl, pyrazolyl, thiazolyl, oxazolyl, carbazolyl, triazolyl, indolyl and purinyl, the substituted or unsubstituted imidazoyl-like group is selected from pyrrolinyl, pyrazolyl, thiazolyl, oxazolyl, carbazolyl, triazolyl, indolyl and purinyl, the substituted or unsubstituted pyrazolyl-like group is selected from pyrrolinyl, pyrazolyl, thiazolyl, oxazolyl, carbazolyl, triazolyl, indolyl and purinyl, and the substituted or unsubstituted boratabenzene-like group is selected from methylboratabenzene, ethylboratabenzene, 1-methyl-3-ethylboratabenzene or other functionalized boratabenzene moieties.

Also, referring to the compounds represented by the formula (L₁)M(L₃)(L₄), M preferably can be selected from Ru, Fe and Os. Other illustrative metals or metalloids include, for example, Ti, Zr, Hf, V, Nb, Ta, Cr, Mo, W, Mn, Tc, Re, Co, Rh, Ir, Ni, Pd, Pt, Cu, Ag, Au, Zn, Cd, Hg, Al, Ga, Si, Ge, a Lanthanide series element or an Actinide series element.

Illustrative compounds represented by the formula (L₁)M(L₃)(L₄) include, for example, methylboratabenzene(allyl)carbonylruthenium(II), (pyrrolyl)trimethylamino(diisopropylacetamidinato)ruthenium(II), (ethylcyclopentadienyl)allyl(carbonyl)ruthenium(II), cyclopentadienyl(2-methylallyl)carbonylruthenium(II), methylboratabenzene(allyl)carbonylosmium(II), (pyrrolyl)trimethylamino(diisopropylacetamidinato)iron(II), (ethylcyclopentadienyl)allyl(carbonyl)osmium(II), cyclopentadienyl(2-methyl-allyl)carbonyliron(II), and allyl(carbonyl)ethylcyclopentadienyliron(II). In an embodiment, the organometallic compounds undergo hydrogen reduction.

Other compounds within the scope of this invention can be represented by the formula (L₁)M(L₄)(L₅)₂ wherein M is a metal or metalloid having a (+4) oxidation state, L₁ is a substituted or unsubstituted anionic 6 electron donor ligand, L₄ is a substituted or unsubstituted anionic 4 electron donor ligand, and L₅ is the same or different and is a substituted or unsubstituted anionic 2 electron donor ligand.

Preferably, M is selected from ruthenium (Ru), iron (Fe) or osmium (Os), L₁ is selected from a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, a substituted or unsubstituted pyrazolyl-like group, a substituted or unsubstituted boratabenzene group, and a substituted or unsubstituted boratabenzene-like group, L₄ is selected from a substituted or unsubstituted allyl, azaallyl, amidinate and betadiketiminate group, and L₅ is selected from a substituted or unsubstituted hydrido, halo and an alkyl group having from 1 to 12 carbon atoms.

The compounds represented by the formula (L₁)M(L₄)(L₅)₂ include those compounds where M is ruthenium (Ru) with a (+4) oxidation number, L₁ is a substituted or unsubstituted anionic 6 electron donor ligand with a (−1) electrical charge, L₄ is a substituted or unsubstituted anionic 4 electron donor ligand with a (−1) electrical charge, and L₅ is the same or different and is a substituted or unsubstituted anionic 2 electron donor ligand with a (−1) electrical charge.

Referring to the compounds represented by the formula (L₁)M(L₄)(L₅)₂, the substituted or unsubstituted cyclopentadienyl-like group is selected from cyclohexadienyl, cycloheptadienyl, cyclooctadienyl, heterocyclic group and aromatic group, the substituted or unsubstituted cycloheptadienyl-like group is selected from cyclohexadienyl, cyclooctadienyl, heterocyclic group and aromatic group, the substituted or unsubstituted pentadienyl-like group is selected from linear olefins, hexadienyl, heptadienyl and octadienyl, the substituted or unsubstituted pyrrolyl-like group is selected from pyrrolinyl, pyrazolyl, thiazolyl, oxazolyl, carbazolyl, triazolyl, indolyl and purinyl, the substituted or unsubstituted imidazoyl-like group is selected from pyrrolinyl, pyrazolyl, thiazolyl, oxazolyl, carbazolyl, triazolyl, indolyl and purinyl, the substituted or unsubstituted pyrazolyl-like group is selected from pyrrolinyl, pyrazolyl, thiazolyl, oxazolyl, carbazolyl, triazolyl, indolyl and purinyl, and the substituted or unsubstituted boratabenzene-like group is selected from methylboratabenzene, ethylboratabenzene, 1-methyl-3-ethylboratabenzene or other functionalized boratabenzene moieties.

Also, referring to the compounds represented by the formula (L₁)M(L₄)(L₅)₂, M preferably can be selected from Ru, Fe and Os. Other illustrative metals or metalloids include, for example, Ti, Zr, Hf, V, Nb, Ta, Cr, Mo, W, Mn, Tc, Re, Co, Rh, Ir, Ni, Pd, Pt, Cu, Ag, Au, Zn, Cd, Hg, Al, Ga, Si, Ge, a Lanthanide series element or an Actinide series element.

Illustrative compounds represented by the formula (L₁)M(L₄)(L₅)₂ include, for example, (ethylcyclopentadienyl)(dimethyl)allylruthenium(IV), (2,5-dimethylpyrrolyl)(dimethyl)allylruthenium(IV), allyl(ethylcyclopentadienyl)dimethylruthenium(IV), (methylboratabenzene)dimethyl(diisopropylacetamidinato)ruthenium(IV), (ethylcyclopentadienyl)(dimethyl)allylosmium(IV), (2,5-dimethylpyrrolyl) (dimethyl)allyliron(IV), (methylboratabenzene)dimethyl(diisopropyl-acetamidinato)osmium(IV), and allyl(ethylcyclopentadienyl)dimethylosmium(IV). In an embodiment, the organometallic compounds undergo hydrogen reduction.

Other compounds within the scope of this invention can be represented by the formula (L₁)M(L₃)₂(L₅) wherein M is a metal or metalloid having a (+2) oxidation state, L₁ is a substituted or unsubstituted anionic 6 electron donor ligand, L₃ is the same or different and is a substituted or unsubstituted neutral 2 electron donor ligand, and L₅ is a substituted or unsubstituted anionic 2 electron donor ligand.

Preferably, M is selected from ruthenium (Ru), iron (Fe) or osmium (Os), L₁ is selected from a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, a substituted or unsubstituted pyrazolyl-like group, a substituted or unsubstituted boratabenzene group, and a substituted or unsubstituted boratabenzene-like group, L₃ is selected from a substituted or unsubstituted carbonyl, phosphino, amino, alkenyl, alkynyl, nitrile and isonitrile group, and L₅ is selected from a substituted or unsubstituted hydrido, halo and an alkyl group having from 1 to 12 carbon atoms.

The compounds represented by the formula (L₁)M(L₃)₂(L₅) include those compounds where M is ruthenium (Ru) with a (+2) oxidation number, L₁ is a substituted or unsubstituted anionic 6 electron donor ligand with a (−1) electrical charge, L₃ is the same or different and is a substituted or unsubstituted neutral 2 electron donor ligand with a zero (0) electrical charge, and L₅ is a substituted or unsubstituted anionic 2 electron donor ligand with a (−1) electrical charge.

Referring to the compounds represented by the formula (L₁)M(L₃)₂(L₅), the substituted or unsubstituted cyclopentadienyl-like group is selected from cyclohexadienyl, cycloheptadienyl, cyclooctadienyl, heterocyclic group and aromatic group, the substituted or unsubstituted cycloheptadienyl-like group is selected from cyclohexadienyl, cyclooctadienyl, heterocyclic group and aromatic group, the substituted or unsubstituted pentadienyl-like group is selected from linear olefins, hexadienyl, heptadienyl and octadienyl, the substituted or unsubstituted pyrrolyl-like group is selected from pyrrolinyl, pyrazolyl, thiazolyl, oxazolyl, carbazolyl, triazolyl, indolyl and purinyl, the substituted or unsubstituted imidazoyl-like group is selected from pyrrolinyl, pyrazolyl, thiazolyl, oxazolyl, carbazolyl, triazolyl, indolyl and purinyl, the substituted or unsubstituted pyrazolyl-like group is selected from pyrrolinyl, pyrazolyl, thiazolyl, oxazolyl, carbazolyl, triazolyl, indolyl and purinyl, and the substituted or unsubstituted boratabenzene-like group is selected from methylboratabenzene, ethylboratabenzene, 1-methyl-3-ethylboratabenzene or other functionalized boratabenzene moieties.

Also, referring to the compounds represented by the formula (L₁)M(L₃)₂(L₅), M preferably can be selected from Ru, Fe and Os. Other illustrative metals or metalloids include, for example, Ti, Zr, Hf, V, Nb, Ta, Cr, Mo, W, Mn, Tc, Re, Co, Rh, Ir, Ni, Pd, Pt, Cu, Ag, Au, Zn, Cd, Hg, Al, Ga, Si, Ge, a Lanthanide series element or an Actinide series element.

Illustrative compounds represented by the formula (L₁)M(L₃)₂(L₅) include, for example, (ethylcyclopentadienyl)dicarbonyl(methyl)ruthenium(II), pyrrolyl(dicarbonyl)(methyl)ruthenium(II), methylboratabenzene-di(trimethylphosphino)methylruthenium(II), (pyrrolyl)methyl(dicarbonyl)iron(II), (ethylcyclopentadienyl)dicarbonyl(methyl)iron(II), pyrrolyl(dicarbonyl)(methyl)osmium(II), and methylboratabenzene-di(trimethylphosphino)methyliron(II). In an embodiment, the organometallic compounds undergo hydrogen reduction.

Other compounds within the scope of this invention can be represented by the formula (L₁)M(L₆) wherein M is a metal or metalloid having a (+2) oxidation state, L₁ is a substituted or unsubstituted anionic 6 electron donor ligand, and L₆ is a substituted or unsubstituted anionic 4 electron donor ligand with a pendant neutral 2 electron donor moiety.

Preferably, M is selected from ruthenium (Ru), iron (Fe) or osmium (Os), L₁ is selected from a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, a substituted or unsubstituted pyrazolyl-like group, a substituted or unsubstituted boratabenzene group, and a substituted or unsubstituted boratabenzene-like group, and L₆ is selected from a substituted or unsubstituted anionic 4 electron donor ligand with a pendant neutral 2 electron donor moiety such as an amidinate with a N-substituted beta or gamma pendant amine.

The compounds represented by the formula (L₁)M(L₆) can include those compounds where M is ruthenium (Ru) with a (+2) oxidation number, L₁ is a substituted or unsubstituted anionic 6 electron donor ligand with a (−1) electrical charge, and L₆ is a substituted or unsubstituted anionic 4 electron donor ligand with a pendant neutral 2 electron donor moiety with a (−1) electrical charge.

Referring to the compounds represented by the formula (L₁)M(L₆), the substituted or unsubstituted cyclopentadienyl-like group is selected from cyclohexadienyl, cycloheptadienyl, cyclooctadienyl, heterocyclic group and aromatic group, the substituted or unsubstituted cycloheptadienyl-like group is selected from cyclohexadienyl, cyclooctadienyl, heterocyclic group and aromatic group, the substituted or unsubstituted pentadienyl-like group is selected from linear olefins, hexadienyl, heptadienyl and octadienyl, the substituted or unsubstituted pyrrolyl-like group is selected from pyrrolinyl, pyrazolyl, thiazolyl, oxazolyl, carbazolyl, triazolyl, indolyl and purinyl, the substituted or unsubstituted imidazoyl-like group is selected from pyrrolinyl, pyrazolyl, thiazolyl, oxazolyl, carbazolyl, triazolyl, indolyl and purinyl, the substituted or unsubstituted pyrazolyl-like group is selected from pyrrolinyl, pyrazolyl, thiazolyl, oxazolyl, carbazolyl, triazolyl, indolyl and purinyl, and the substituted or unsubstituted boratabenzene-like group is selected from methylboratabenzene, ethylboratabenzene, 1-methyl-3-ethylboratabenzene or other functionalized boratabenzene moieties.

Also, referring to the compounds represented by the formula (L₁)M(L₆), M preferably can be selected from Ru, Fe and Os. Other illustrative metals or metalloids include, for example, Ti, Zr, Hf, V, Nb, Ta, Cr, Mo, W, Mn, Tc, Re, Co, Rh, Ir, Ni, Pd, Pt, Cu, Ag, Au, Zn, Cd, Hg, Al, Ga, Si, Ge, a Lanthanide series element or an Actinide series element.

Illustrative compounds represented by the formula (L₁)M(L₆) include, for example, [ⁱPrNCCH₃N(CH₂)₃N(CH₃)₂](ethylcyclopentadienyl)ruthenium(II), [EtNCCH₃N(CH₂)₂N(CH₃)₂] (cyclopentadienyl)ruthenium(II), [H₂CCHCH(CH₂)₃N(CH₃)₂] (ethylcyclopentadienyl)ruthenium(II), [H₂CCHCH(CH₂)₂(HC═CH₂)](pyrrolyl)ruthenium(II), [ⁱPrNCCH₃N(CH₂)₃N(CH₃)₂](methylboratabenzene)ruthenium(II), [ⁱPrNCCH₃N(CH₂)₃N(CH₃)₂](ethylcyclopentadienyl)osmium(II), [ⁱPrNCCH₃N(CH₂)₃N(CH₃)₂](methylboratabenzene)osmium(II), [ⁱPrNCCH₃N(CH₂)₃N(CH₃)₂](ethylcyclopentadienyl)iron(II), [EtNCCH₃N(CH₂)₂N(CH₃)₂](cyclopentadienyl)osmium(II), [H₂CCHCH(CH₂)₃N(CH₃)₂](ethylcyclopentadienyl)osmium(II), and [H₂CCHCH(CH₂)₂(HC═CH₂)](pyrrolyl)iron(II). In an embodiment, the organometallic compounds undergo hydrogen reduction.

This invention in part provides organometallic precursor compounds and a method of processing a substrate to form a metal-based material layer, e.g., ruthenium layer, on the substrate by CVD or ALD of the organometallic precursor compound. The metal-based material layer is deposited on a heated substrate by thermal or plasma enhanced dissociation of the organometallic precursor compound having the formulae above in the presence of a processing gas. The processing gas may be an inert gas, such as helium and argon, and combinations thereof. The composition of the processing gas is selected to deposit metal-based material layers, e.g., ruthenium layers, as desired.

For the organometallic precursor compounds of this invention represented by the formula above, M, represents the metal to be deposited. Examples of metals which can be deposited according to this invention are Ru, Fe and Os. Other illustrative metals or metalloids include, for example, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Hg, Al, Ga, Si, Ge, a Lanthanide series element or an Actinide series element.

Illustrative substituted and unsubstituted anionic ligands (L₁) useful in this invention include, for example, 6 electron anionic donor ligands such as cyclopentadienyl (Cp), cycloheptadienyl, pentadienyl, pyrrolyl, boratabenzyl, pyrazolyl, imidazolyl, and the like. Cp is a cyclopentadienyl ring having the general formula (C₅H₅—) which forms a ligand with the metal, M. The cyclopentadienyl ring may be substituted, thereby having the formula (Cp(R′). The precursor contains one 6 electron anionic donor ligand group, e.g., cyclopentadienyl groups.

Other illustrative substituted and unsubstituted 6 electron anionic donor ligands include cyclodienyl complexes, e.g., cyclohexadienyl, cycloheptadienyl, cyclooctadienyl rings, heterocyclic rings, aromatic rings, such as substituted cyclopentadienyl ring like ethylcyclopentadienyl, and others, as known in the art.

Illustrative ligands (L₂) useful in this invention include, for example, (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety.

Illustrative substituted and unsubstituted anionic ligands (L₄) useful in this invention include, for example, 4 electron anionic donor ligands such as allyl, azaallyl, amidinate, betadiketiminate, and the like.

Illustrative substituted and unsubstituted anionic ligands (L₅) useful in this invention include, for example, 2 electron anionic donor ligands such as hybrido, halo, alkyl, and the like.

Illustrative substituted and unsubstituted neutral ligands (L₃) useful in this invention include, for example, 2 electron neutral donor ligands such as carbonyl, phosphino, amino, alkenyl, alkynyl, nitrile, isonitrile, and the like.

Illustrative substituted and unsubstituted anionic ligands (L₆) useful in this invention include, for example, 4 electron anionic donor ligands with a pendant neutral 2 electron donor moiety such as amino-amidinates (e.g., [EtNCCH₃N(CH₂)₂N(CH₃)₂]), amino-allyls (e.g., [H₂CCHCH(CH₂)₂N(CH₃)₂]), alkene-amidinates (e.g., [EtNCCH₃N(CH₂)₂(CH═CH₂)]), alkene-allyls (e.g., [H₂CCHCH(CH₂)₂(HC═CH₂)]), and the like.

Permissible substituents of the substituted ligands used herein include halogen atoms, acyl groups having from 1 to about 12 carbon atoms, alkoxy groups having from 1 to about 12 carbon atoms, alkoxycarbonyl groups having from 1 to about 12 carbon atoms, alkyl groups having from 1 to about 12 carbon atoms, amine groups having from 1 to about 12 carbon atoms or silyl groups having from 0 to about 12 carbon atoms.

Illustrative halogen atoms include, for example, fluorine, chlorine, bromine and iodine. Preferred halogen atoms include chlorine and fluorine.

Illustrative acyl groups include, for example, formyl, acetyl, propionyl, butyryl, isobutyryl, valeryl, 1-methylpropylcarbonyl, isovaleryl, pentylcarbonyl, 1-methylbutylcarbonyl, 2-methylbutylcarbonyl, 3-methylbutylcarbonyl, 1-ethylpropylcarbonyl, 2-ethylpropylcarbonyl, and the like. Preferred acyl groups include formyl, acetyl and propionyl.

Illustrative alkoxy groups include, for example, methoxy, ethoxy, n-propoxy, isopropoxy, n-butoxy, isobutoxy, sec-butoxy, tert-butoxy, pentyloxy, 1-methylbutyloxy, 2-methylbutyloxy, 3-methylbutyloxy, 1,2-dimethylpropyloxy, hexyloxy, 1-methylpentyloxy, 1-ethylpropyloxy, 2-methylpentyloxy, 3-methylpentyloxy, 4-methylpentyloxy, 1,2-dimethylbutyloxy, 1,3-dimethylbutyloxy, 2,3-dimethylbutyloxy, 1,1-dimethylbutyloxy, 2,2-dimethylbutyloxy, 3,3-dimethylbutyloxy, and the like. Preferred alkoxy groups include methoxy, ethoxy and propoxy.

Illustrative alkoxycarbonyl groups include, for example, methoxycarbonyl, ethoxycarbonyl, propoxycarbonyl, isopropoxycarbonyl, cyclopropoxycarbonyl, butoxycarbonyl, isobutoxycarbonyl, sec-butoxycarbonyl, tert-butoxycarbonyl, and the like. Preferred alkoxycarbonyl groups include methoxycarbonyl, ethoxycarbonyl, propoxycarbonyl, isopropoxycarbonyl and cyclopropoxycarbonyl.

Illustrative alkyl groups include, for example, methyl, ethyl, n-propyl, isopropyl, n-butyl, isobutyl, sec-butyl, tert-butyl, pentyl, isopentyl, neopentyl, tert-pentyl, 1-methylbutyl, 2-methylbutyl, 1,2-dimethylpropyl, hexyl, isohexyl, 1-methylpentyl, 2-methylpentyl, 3-methylpentyl, 1,1-dimethylbutyl, 2,2-dimethylbutyl, 1,3-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl, 1-ethyl-2-methylpropyl, cyclopropyl, cyclobutyl, cyclopentyl, cyclohexyl, cyclopropylmethyl, cyclopropylethyl, cyclobutylmethyl, and the like. Preferred alkyl groups include methyl, ethyl, n-propyl, isopropyl and cyclopropyl.

Illustrative amine groups include, for example, methylamine, dimethylamine, ethylamine, diethylamine, propylamine, dipropylamine, isopropylamine, diisopropylamine, butylamine, dibutylamine, tert-butylamine, di(tert-butyl)amine, ethylmethylamine, butylmethylamine, cyclohexylamine, dicyclohexylamine, and the like. Preferred amine groups include dimethylamine, diethylamine and diisopropylamine.

Illustrative silyl groups include, for example, silyl, trimethylsilyl, triethylsilyl, tris(trimethylsilyl)methyl, trisilylmethyl, methylsilyl and the like. Preferred silyl groups include silyl, trimethylsilyl and triethylsilyl.

In a preferred embodiment, this invention relates in part to ruthenium compounds represented by the following formulae:

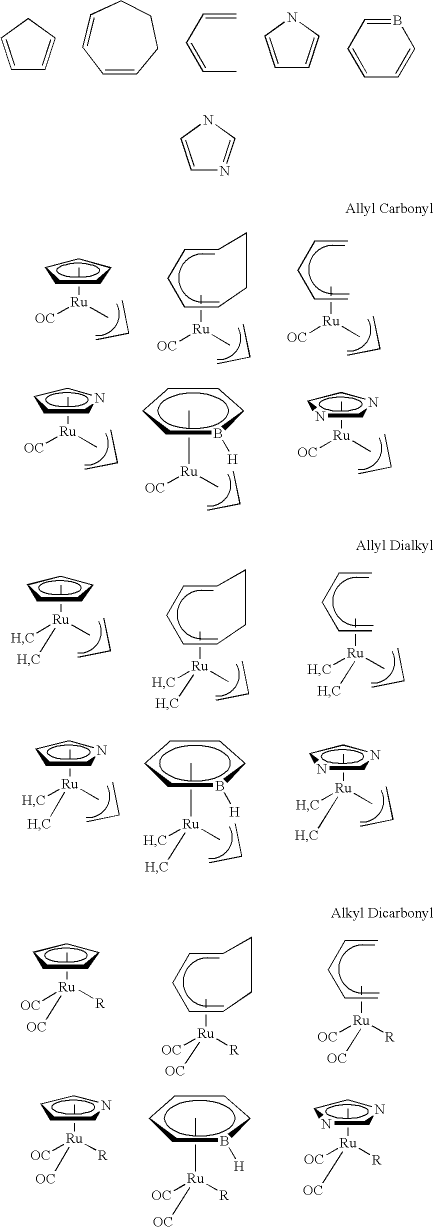

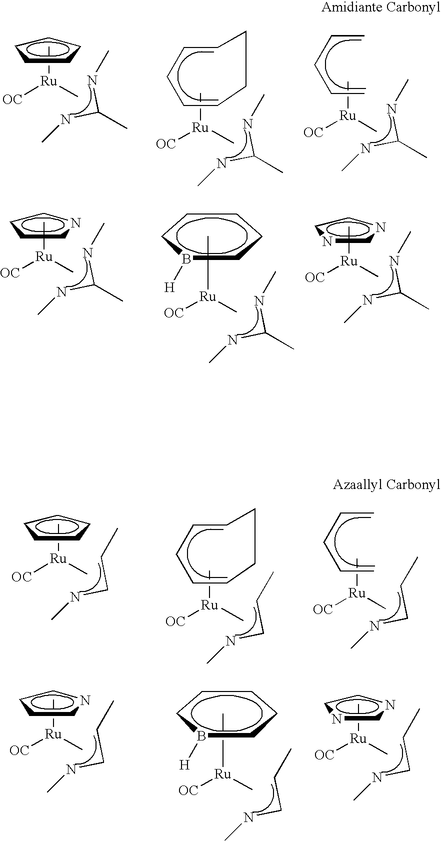

As indicated above, this invention also relates to mixtures comprising (i) a first organometallic precursor compound represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0, and (ii) one or more different organometallic precursor compounds (e.g., a hafnium-containing, tantalum-containing or molybdenum-containing organometallic precursor compound).

It is believed that the presence of the above donor ligand groups enhances preferred physical properties. It is believed that appropriate choice of these substituent groups can increase organometallic precursor volatility, decrease or increase the temperature required to dissociate the precursor, and lower the boiling point of the organometallic precursor. An increased volatility of the organometallic precursor compounds ensures a sufficiently high concentration of precursor entrained in vaporized fluid flow to the processing chamber for effective deposition of a layer. The improved volatility will also allow the use of vaporization of the organometallic precursor by sublimation and delivery to a processing chamber without risk of premature dissociation. Additionally, the presence of the above donor substituent groups may also provide sufficient solubility of the organometallic precursor for use in liquid delivery systems.

It is believed that appropriate selection of the donor ligand groups for the organometallic precursors described herein allows the formation of heat decomposable organometallic compounds that are thermally stable at temperatures below about 150° C. and that are capable of thermally dissociating at temperatures above about 150° C. The organometallic precursors are also capable of dissociation in a plasma generated by supplying a power density at about 0.6 Watts/cm² or greater, or at about 200 Watts or greater for a 200 mm substrate, to a processing chamber.

The organometallic precursors described herein may deposit metal layers depending on the processing gas composition and the plasma gas composition for the deposition process. A metal layer is deposited in the presence of inert processing gases such as argon, a reactant processing gas, such as hydrogen, and combinations thereof.

It is believed that the use of a reactant processing gas, such as hydrogen, facilitates reaction with the 6 electron anionic donor groups to form volatile species that may be removed under low pressure, thereby removing the substituents from the precursor and depositing a metal layer on the substrate. The metal layer is preferably deposited in the presence of argon.

An exemplary processing regime for depositing a layer from the above described precursor is as follows. A precursor having the composition described herein, such as (ethylcyclopentadienyl)carbonyl(allyl)ruthenium, and a processing gas are introduced into a processing chamber. The precursor is introduced at a flow rate between about 5 and about 500 sccm and the processing gas is introduced into the chamber at a flow rate of between about 5 and about 500 sccm. In one embodiment of the deposition process, the precursor and processing gas are introduced at a molar ratio of about 1:1. The processing chamber is maintained at a pressure between about 100 milliTorr and about 20 Torr. The processing chamber is preferably maintained at a pressure between about 100 milliTorr and about 250 milliTorr. Flow rates and pressure conditions may vary for different makes, sizes, and models of the processing chambers used.

Thermal dissociation of the precursor involves heating the substrate to a temperature sufficiently high to cause the hydrocarbon portion of the volatile metal compound adjacent the substrate to dissociate to volatile hydrocarbons which desorb from the substrate while leaving the metal on the substrate. The exact temperature will depend upon the identity and chemical, thermal, and stability characteristics of the organometallic precursor and processing gases used under the deposition conditions. However, a temperature from about room temperature to about 400° C. is contemplated for the thermal dissociation of the precursor described herein.

The thermal dissociation is preferably performed by heating the substrate to a temperature between about 100° C. and about 600° C. In one embodiment of the thermal dissociation process, the substrate temperature is maintained between about 250° C. and about 450° C. to ensure a complete reaction between the precursor and the reacting gas on the substrate surface. In another embodiment, the substrate is maintained at a temperature below about 400° C. during the thermal dissociation process.

For plasma-enhanced CVD processes, power to generate a plasma is then either capacitively or inductively coupled into the chamber to enhance dissociation of the precursor and increase reaction with any reactant gases present to deposit a layer on the substrate. A power density between about 0.6 Watts/cm² and about 3.2 Watts/cm², or between about 200 and about 1000 Watts, with about 750 Watts most preferably used for a 200 mm substrate, is supplied to the chamber to generate the plasma.

After dissociation of the precursor and deposition of the material on the substrate, the deposited material may be exposed to a plasma treatment. The plasma comprises a reactant processing gas, such as hydrogen, an inert gas, such as argon, and combinations thereof. In the plasma-treatment process, power to generate a plasma is either capacitively or inductively coupled into the chamber to excite the processing gas into a plasma state to produce plasma specie, such as ions, which may react with the deposited material. The plasma is generated by supplying a power density between about 0.6 Watts/cm² and about 3.2 Watts/cm², or between about 200 and about 1000 Watts for a 200 mm substrate, to the processing chamber.

In one embodiment the plasma treatment comprises introducing a gas at a rate between about 5 sccm and about 300 sccm into a processing chamber and generating a plasma by providing power density between about 0.6 Watts/cm² and about 3.2 Watts/cm², or a power at between about 200 Watts and about 1000 Watts for a 200 mm substrate, maintaining the chamber pressure between about 50 milliTorr and about 20 Torr, and maintaining the substrate at a temperature of between about 100° C. and about 400° C. during the plasma process.

It is believed that the plasma treatment lowers the layer's resistivity, removes contaminants, such as carbon or excess hydrogen, and densifies the layer to enhance barrier and liner properties. It is believed that species from reactant gases, such as hydrogen species in the plasma react with the carbon impurities to produce volatile hydrocarbons that can easily desorb from the substrate surface and can be purged from the processing zone and processing chamber. Plasma species from inert gases, such as argon, further bombard the layer to remove resistive constituents to lower the layers resistivity and improve electrical conductivity.

Plasma treatments are preferably not performed for metal layers, since the plasma treatment may remove the desired carbon content of the layer. If a plasma treatment for a metal layer is performed, the plasma gases preferably comprise inert gases, such as argon and helium, to remove carbon.

It is believed that depositing layers from the above identified precursors and exposing the layers to a post deposition plasma process will produce a layer with improved material properties. The deposition and/or treatment of the materials described herein are believed to have improved diffusion resistance, improved interlayer adhesion, improved thermal stability, and improved interlayer bonding.

In an embodiment of this invention, a method for metallization of a feature on a substrate is provided that comprises depositing a dielectric layer on the substrate, etching a pattern into the substrate, depositing a metal layer on the dielectric layer, and depositing a conductive metal layer on the metal layer. The substrate may be optionally exposed to reactive pre-clean comprising a plasma of hydrogen and argon to remove oxide formations on the substrate prior to deposition of the metal layer. The conductive metal is preferably copper and may be deposited by physical vapor deposition, chemical vapor deposition, or electrochemical deposition. The metal layer is deposited by the thermal or plasma enhanced dissociation of an organometallic precursor of this invention in the presence of a processing gas, preferably at a pressure less than about 20 Torr. Once deposited, the metal layer can be exposed to a plasma prior to subsequent layer deposition.

Current copper integration schemes involve a diffusion barrier with a copper wetting layer on top followed by a copper seed layer. A layer of metal gradually becoming metal rich in accordance with this invention would replace multiple steps in the current integration schemes. The metal layer is an excellent barrier to copper diffusion due to its amorphous character. The metalrich layer functions as a wetting layer and may allow for direct plating onto the metal. This single layer could be deposited in one step by manipulating the deposition parameters during the deposition. A post deposition treatment may also be employed to increase the ratio of metal in the film. Removal of one or more steps in semiconductor manufacture will result in substantial savings to the semiconductor manufacturer.

Metal films are deposited at temperatures lower than 400° C. and form no corrosive byproducts. The metal films are amorphous and are superior barriers to copper diffusion. By tuning the deposition parameters and post deposition treatment, the metal barrier can have a metal rich film deposited on top of it. This metal rich film acts as a wetting layer for copper and may allow for direct copper plating on top of the metal layer. In an embodiment, the deposition parameters may be tuned to provide a layer in which the composition varies across the thickness of the layer. For example, the layer may be metal rich at the silicon portion surface of the microchip, e.g., good barrier properties, and metal rich at the copper layer surface, e.g., good adhesive properties.

As also indicated above, this invention relates in part to a process for producing an organometallic compound having the formula (L₁)M(L₃)(L₄) wherein M is a metal or metalloid having a (+2) oxidation state, L₁ is a substituted or unsubstituted anionic 6 electron donor ligand, L₃ is a substituted or unsubstituted neutral 2 electron donor ligand, and L₄ is a substituted or unsubstituted anionic 4 electron donor ligand; which process comprises reacting a metal halide and a first salt in the presence of a first solvent and under reaction conditions sufficient to produce an intermediate reaction material, and reacting said intermediate reaction material with a second salt in the presence of a second solvent and under reaction conditions sufficient to produce said organometallic compound. The organometallic compound yield resulting from the process of this invention can be 40% or greater, preferably 35% or greater, and more preferably 30% or greater.

The process is particularly well-suited for large scale production since it can be conducted using the same equipment, some of the same reagents and process parameters that can easily be adapted to manufacture a wide range of products. The process provides for the synthesis of organometallic precursor compounds using a process where all manipulations can be carried out in a single vessel, and which route to the organometallic precursor compounds does not require the isolation of an intermediate complex.

The metal halide compound starting material may be selected from a wide variety of compounds known in the art. The invention herein most prefers metals selected from Ru, Fe and Os. Other illustrative metals include, for example, Ti, Zr, Hf, V, Nb, Ta, Cr, Mo, W, Mn, Tc, Re, Co, Rh, Ir, Ni, Pd, Pt, Cu, Ag, Au, Zn, Cd, Hg, Al, Ga, Si, Ge, a Lanthanide series element or an Actinide series element. Illustrative metal halide compounds include, for example, [Ru(CO)₃Cl₂]₂, Ru(PPh₃)₃Cl₂, Ru(PPh₃)₄Cl₂, [Ru(C₆H₆)Cl₂]₂, Ru(NCCH₃)₄Cl₂, and the like.

The concentration of the metal source compound starting material can vary over a wide range, and need only be that minimum amount necessary to react with the first salt to produce the intermediate reaction material and to provide the given metal concentration desired to be employed and which will furnish the basis for at least the amount of metal necessary for the organometallic compounds of this invention. In general, depending on the size of the reaction mixture, metal source compound starting material concentrations in the range of from about 1 millimole or less to about 10,000 millimoles or greater, should be sufficient for most processes.

The first salt starting material may be selected from a wide variety of compounds known in the art. Illustrative first salts include lithium 2,5-dimethylpyrrolide, sodium cyclopentadienide, potassium cyclopentadienide, lithium cyclopentadienide, potassium methylboratabenzene, lithium ethylcyclopentadienide, and the like. The first salt starting material is preferably sodium cyclopentadienide and the like.

The concentration of the first salt starting material can vary over a wide range, and need only be that minimum amount necessary to react with the metal source compound starting material to produce an intermediate reaction material. In general, depending on the size of the first reaction mixture, salt starting material concentrations in the range of from about 1 millimole or less to about 10,000 millimoles or greater, should be sufficient for most processes.

The first solvent employed in the method of this invention may be any saturated and unsaturated hydrocarbons, aromatic hydrocarbons, aromatic heterocycles, alkyl halides, silylated hydrocarbons, ethers, polyethers, thioethers, esters, thioesters, lactones, amides, amines, polyamines, silicone oils, other aprotic solvents, or mixtures of one or more of the above; more preferably, diethylether, pentanes, or dimethoxyethanes; and most preferably tetrahydrofuran (THF), toluene or dimethoxyethane (DME) or mixtures thereof. Any suitable solvent which does not unduly adversely interfere with the intended reaction can be employed. Mixtures of one or more different solvents may be employed if desired. The amount of solvent employed is not critical to the subject invention and need only be that amount sufficient to solubilize the reaction components in the reaction mixture. In general, the amount of solvent may range from about 5 percent by weight up to about 99 percent by weight or more based on the total weight of the reaction mixture starting materials.

Reaction conditions for the reaction of the first salt compound with the metal source compound to produce the intermediate reaction material, such as temperature, pressure and contact time, may also vary greatly and any suitable combination of such conditions may be employed herein. The reaction temperature may be the reflux temperature of any of the aforementioned solvents, and more preferably between about −80° C. to about 150° C., and most preferably between about 20° C. to about 120° C. Normally the reaction is carried out under ambient pressure and the contact time may vary from a matter of seconds or minutes to a few hours or greater. The reactants can be added to the reaction mixture or combined in any order. The stir time employed can range from about 0.1 to about 400 hours, preferably from about 1 to 75 hours, and more preferably from about 4 to 16 hours, for all steps.

The intermediate reaction material may be selected from a wide variety of materials known in the art. Illustrative intermediate reaction materials include (2,5-dimethylpyrrolyl)dicarbonylchlororuthenium, (EtCp)Ru(PPh3)₂Cl, (pyrrolyl)(DPPE)ClRu, (EtCp)RuCl₂(allyl), (pyrrolyl)Ru(CO)₂Cl, and the like. The preferred intermediate reaction material is dependent on the oxidation state and the type of complex desired. It is frequently preferably (EtCp)Ru(PPh3)₂Cl, (EtCp)RuCl₂(allyl), (pyrrolyl)Ru(CO)₂Cl, and similar complexes. The process of this invention does not require isolation of the intermediate reaction material.

The concentration of the intermediate reaction material can vary over a wide range, and need only be that minimum amount necessary to react with the second salt material to produce the organometallic compounds of this invention. In general, depending on the size of the second reaction mixture, intermediate reaction material concentrations in the range of from about 1 millimole or less to about 10,000 millimoles or greater, should be sufficient for most processes.

The second salt starting material may be selected from a wide variety of compounds known in the art. Illustrative second salts include lithium 1,3-diisopropylacetamidinate, 2-methylallylmagnesiumbromide, lithium 2,5-dimethylpyrrolylide, lithium methylboratabenzene, and the like. The second salt starting material is preferably 2,5-dimethylpyrrolylide and the like.

The concentration of the second salt starting material can vary over a wide range, and need only be that minimum amount necessary to react with the intermediate reaction material to produce the organometallic compounds of this invention. In general, depending on the size of the first reaction mixture, second salt material concentrations in the range of from about 1 millimole or less to about 10,000 millimoles or greater, should be sufficient for most processes.

The second solvent employed in the method of this invention may be any saturated and unsaturated hydrocarbons, aromatic hydrocarbons, aromatic heterocycles, alkyl halides, silylated hydrocarbons, ethers, polyethers, thioethers, esters, thioesters, lactones, amides, amines, polyamines, silicone oils, other aprotic solvents, or mixtures of one or more of the above; more preferably, diethylether, pentanes, or dimethoxyethanes; and most preferably toluene, hexane or mixtures thereof. Any suitable solvent which does not unduly adversely interfere with the intended reaction can be employed. Mixtures of one or more different solvents may be employed if desired. The amount of solvent employed is not critical to the subject invention and need only be that amount sufficient to solubilize the reaction components in the reaction mixture. In general, the amount of solvent may range from about 5 percent by weight up to about 99 percent by weight or more based on the total weight of the reaction mixture starting materials.

Reaction conditions for the reaction of the intermediate reaction material with the second salt material to produce the organometallic precursors of this invention, such as temperature, pressure and contact time, may also vary greatly and any suitable combination of such conditions may be employed herein. The reaction temperature may be the reflux temperature of any of the aforementioned solvents, and more preferably between about −80° C. to about 150° C., and most preferably between about 20° C. to about 120° C. Normally the reaction is carried out under ambient pressure and the contact time may vary from a matter of seconds or minutes to a few hours or greater. The reactants can be added to the reaction mixture or combined in any order. The stir time employed can range from about 0.1 to about 400 hours, preferably from about 1 to 75 hours, and more preferably from about 4 to 16 hours, for all steps.

Isolation of the complex may be achieved by filtering to remove solids, reduced pressure to remove solvent, and distillation (or sublimation) to afford the final pure compound. Chromatography may also be employed as a final purification method.

This invention also relates to another process for producing an organometallic compound having the formula (L₁)M(L₄)(L₅)₂ wherein M is a metal or metalloid having a (+4) oxidation state, L₁ is a substituted or unsubstituted anionic 6 electron donor ligand, L₄ is a substituted or unsubstituted anionic 4 electron donor ligand, and L₅ is the same or different and is a substituted or unsubstituted anionic 2 electron donor ligand; which process comprises reacting a metal halide and a first salt in the presence of a first solvent and under reaction conditions sufficient to produce a first intermediate reaction material, reacting said first intermediate reaction material with a second salt in the presence of a second solvent and under reaction conditions sufficient to produce a second intermediate reaction material, and reacting said second intermediate reaction material with an alkylating agent in the presence of a third solvent and under reaction conditions sufficient to produce said organometallic compound. The organometallic compound yield resulting from the process of this invention can be 40% or greater, preferably 35% or greater, and more preferably 30% or greater.

The process is particularly well-suited for large scale production since it can be conducted using the same equipment, some of the same reagents and process parameters that can easily be adapted to manufacture a wide range of products. The process provides for the synthesis of organometallic precursor compounds using a process where all manipulations can be carried out in a single vessel, and which route to the organometallic precursor compounds does not require the isolation of an intermediate complex.

The metal halide compound starting material may be selected from a wide variety of compounds known in the art. The invention herein most prefers metals selected from Ru, Fe and Os. Other illustrative metals include, for example, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Hg, Al, Ga, Si, Ge, a Lanthanide series element or an Actinide series element. Illustrative metal halide compounds include, for example, [Ru(CO)₃Cl₂]₂, Ru(PPh₃)₃Cl₂, Ru(PPh₃)₄Cl₂, [Ru(C₆H₆)Cl₂]₂, Ru(NCCH₃)₄Cl₂, CpRu(CO)₂Cl, and the like.

The concentration of the metal source compound starting material can vary over a wide range, and need only be that minimum amount necessary to react with the first salt to produce the first intermediate reaction material and to provide the given metal concentration desired to be employed and which will furnish the basis for at least the amount of metal necessary for the organometallic compounds of this invention. In general, depending on the size of the reaction mixture, metal source compound starting material concentrations in the range of from about 1 millimole or less to about 10,000 millimoles or greater, should be sufficient for most processes.

The first salt starting material may be selected from a wide variety of compounds known in the art. Illustrative first salts include lithium 2,5-dimethylpyrrolide, sodium cyclopentadienide, potassium cyclopentadienide, lithium cyclopentadienide, potassium methylboratabenzene, lithium 2,4-dimethylpentadienide, and the like. The first salt starting material is preferably sodium cyclopentadienide and the like.

The concentration of the first salt starting material can vary over a wide range, and need only be that minimum amount necessary to react with the metal source compound starting material to produce the first intermediate reaction material. In general, depending on the size of the first reaction mixture, salt starting material concentrations in the range of from about 1 millimole or less to about 10,000 millimoles or greater, should be sufficient for most processes.

The first solvent employed in the method of this invention may be any saturated and unsaturated hydrocarbons, aromatic hydrocarbons, aromatic heterocycles, alkyl halides, silylated hydrocarbons, ethers, polyethers, thioethers, esters, thioesters, lactones, amides, amines, polyamines, silicone oils, other aprotic solvents, or mixtures of one or more of the above; more preferably, diethylether, pentanes, or dimethoxyethanes; and most preferably tetrahydrofuran (THF), toluene or dimethoxyethane (DME) or mixtures thereof. Any suitable solvent which does not unduly adversely interfere with the intended reaction can be employed. Mixtures of one or more different solvents may be employed if desired. The amount of solvent employed is not critical to the subject invention and need only be that amount sufficient to solubilize the reaction components in the reaction mixture. In general, the amount of solvent may range from about 5 percent by weight up to about 99 percent by weight or more based on the total weight of the reaction mixture starting materials.

Reaction conditions for the reaction of the first salt compound with the metal source compound to produce the first intermediate reaction material, such as temperature, pressure and contact time, may also vary greatly and any suitable combination of such conditions may be employed herein. The reaction temperature may be the reflux temperature of any of the aforementioned solvents, and more preferably between about −80° C. to about 150° C., and most preferably between about 20° C. to about 120° C. Normally the reaction is carried out under ambient pressure and the contact time may vary from a matter of seconds or minutes to a few hours or greater. The reactants can be added to the reaction mixture or combined in any order. The stir time employed can range from about 0.1 to about 400 hours, preferably from about 1 to 75 hours, and more preferably from about 4 to 16 hours, for all steps.

The first intermediate reaction material may be selected from a wide variety of materials known in the art. Illustrative intermediate reaction materials include (2,5-dimethylpyrrolyl)dicarbonylruthenium, (EtCp)Ru(PPh3)₂Cl, (EtCp)Ru(CO)₂Cl, (pyrrolyl)Ru(CO)₂Cl, (methylboratabenzene)Ru(PMe₃)₂Cl, CpRu(CO)₂Cl, and the like. The first intermediate reaction material is preferably (EtCp)Ru(PPh3)₂Cl or CpRu(CO)₂Cl. The process of this invention does not require isolation of the first intermediate reaction material.

The concentration of the first intermediate reaction material can vary over a wide range, and need only be that minimum amount necessary to react with the second salt starting material. In general, depending on the size of the second reaction mixture, first intermediate reaction material concentrations in the range of from about 1 millimole or less to about 10,000 millimoles or greater, should be sufficient for most processes.

The second salt starting material may be selected from a wide variety of compounds known in the art. Illustrative second salts include methyllithium, ethylmagnesiumbromide, and the like. The second salt starting material is preferably methyllithium and the like.

The concentration of the second salt starting material can vary over a wide range, and need only be that minimum amount necessary to react with the first intermediate reaction material to produce a second intermediate reaction material. In general, depending on the size of the first reaction mixture, salt starting material concentrations in the range of from about 1 millimole or less to about 10,000 millimoles or greater, should be sufficient for most processes.

The second solvent employed in the method of this invention may be any saturated and unsaturated hydrocarbons, aromatic hydrocarbons, aromatic heterocycles, alkyl halides, silylated hydrocarbons, ethers, polyethers, thioethers, esters, thioesters, lactones, amides, amines, polyamines, silicone oils, other aprotic solvents, or mixtures of one or more of the above; more preferably, diethylether, pentanes, or dimethoxyethanes; and most preferably toluene, hexane or mixtures thereof. Any suitable solvent which does not unduly adversely interfere with the intended reaction can be employed. Mixtures of one or more different solvents may be employed if desired. The amount of solvent employed is not critical to the subject invention and need only be that amount sufficient to solubilize the reaction components in the reaction mixture. In general, the amount of solvent may range from about 5 percent by weight up to about 99 percent by weight or more based on the total weight of the reaction mixture starting materials.

Reaction conditions for the reaction of the first intermediate reaction material with the second salt material to produce the second intermediate reaction material, such as temperature, pressure and contact time, may also vary greatly and any suitable combination of such conditions may be employed herein. The reaction temperature may be the reflux temperature of any of the aforementioned solvents, and more preferably between about −80° C. to about 150° C., and most preferably between about 20° C. to about 120° C. Normally the reaction is carried out under ambient pressure and the contact time may vary from a matter of seconds or minutes to a few hours or greater. The reactants can be added to the reaction mixture or combined in any order. The stir time employed can range from about 0.1 to about 400 hours, preferably from about 1 to 75 hours, and more preferably from about 4 to 16 hours, for all steps.

The second intermediate reaction material may be selected from a wide variety of materials known in the art. Illustrative second intermediate reaction materials include CpRu(CO)₂Cl, (pyrrolyl)Ru(CO)₂Br, CpRu(CO)₂Br, and the like. The second intermediate reaction material is preferably CpRu(CO)₂Br. The process of this invention does not require isolation of the second intermediate reaction material.

The concentration of the second intermediate reaction material can vary over a wide range, and need only be that minimum amount necessary to react with the alkylating material to produce the organometallic compounds of this invention. In general, depending on the size of the second reaction mixture, second intermediate reaction material concentrations in the range of from about 1 millimole or less to about 10,000 millimoles or greater, should be sufficient for most processes.

The alkylating agent may be selected from a wide variety of compounds known in the art. Illustrative alkylating agents include methyllithium, ethylmagnesiumbromide, and the like. The alkylating agent is preferably methyllithium and the like.

The concentration of the alkylating agent can vary over a wide range, and need only be that minimum amount necessary to react with the second intermediate reaction material to produce the organometallic compounds of this invention. In general, depending on the size of the second reaction mixture, alkylating agent concentrations in the range of from about 1 millimole or less to about 10,000 millimoles or greater, should be sufficient for most processes.

The third solvent employed in the method of this invention may be any saturated and unsaturated hydrocarbons, aromatic hydrocarbons, aromatic heterocycles, alkyl halides, silylated hydrocarbons, ethers, polyethers, thioethers, esters, thioesters, lactones, amides, amines, polyamines, silicone oils, other aprotic solvents, or mixtures of one or more of the above; more preferably, diethylether, pentanes, or dimethoxyethanes; and most preferably toluene, hexane or mixtures thereof. Any suitable solvent which does not unduly adversely interfere with the intended reaction can be employed. Mixtures of one or more different solvents may be employed if desired. The amount of solvent employed is not critical to the subject invention and need only be that amount sufficient to solubilize the reaction components in the reaction mixture. In general, the amount of solvent may range from about 5 percent by weight up to about 99 percent by weight or more based on the total weight of the reaction mixture starting materials.

Reaction conditions for the reaction of the second intermediate reaction material with the alkylating agent to produce the organometallic precursors of this invention, such as temperature, pressure and contact time, may also vary greatly and any suitable combination of such conditions may be employed herein. The reaction temperature may be the reflux temperature of any of the aforementioned solvents, and more preferably between about −80° C. to about 150° C., and most preferably between about 20° C. to about 120° C. Normally the reaction is carried out under ambient pressure and the contact time may vary from a matter of seconds or minutes to a few hours or greater. The reactants can be added to the reaction mixture or combined in any order. The stir time employed can range from about 0.1 to about 400 hours, preferably from about 1 to 75 hours, and more preferably from about 4 to 16 hours, for all steps.

Isolation of the complex may be achieved by filtering to remove solids, reduced pressure to remove solvent, and distillation (or sublimation) to afford the final pure compound. Chromatography may also be employed as a final purification method.

This invention further relates to a process for producing an organometallic compound having the formula (L₁)M(L₃)₂(L₅) wherein M is a metal or metalloid having a (+2) oxidation state, L₁ is a substituted or unsubstituted anionic 6 electron donor ligand, L₃ is the same or different and is a substituted or unsubstituted neutral 2 electron donor ligand, and L₅ is a substituted or unsubstituted anionic 2 electron donor ligand; which process comprises reacting a metal halide and a salt in the presence of a solvent and under reaction conditions sufficient to produce an intermediate reaction material, and reacting said intermediate reaction material with an alkyl source compound in the presence of a second solvent and under reaction conditions sufficient to produce said organometallic compound. The organometallic compound yield resulting from the process of this invention can be 40% or greater, preferably 35% or greater, and more preferably 30% or greater.

The process is particularly well-suited for large scale production since it can be conducted using the same equipment, some of the same reagents and process parameters that can easily be adapted to manufacture a wide range of products. The process provides for the synthesis of organometallic precursor compounds using a process where all manipulations can be carried out in a single vessel, and which route to the organometallic precursor compounds does not require the isolation of an intermediate complex.

The metal halide compound starting material may be selected from a wide variety of compounds known in the art. The invention herein most prefers metals selected from Ru, Fe and Os. Other illustrative metals include, for example, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Hg, Al, Ga, Si, Ge, a Lanthanide series element or an Actinide series element. Illustrative metal halide compounds include, for example, [Ru(CO)₃Cl₂]₂, Ru(PPh₃)₃Cl₂, Ru(PPh₃)₄Cl₂, [Ru(C₆H₆)Cl₂]₂, Ru(NCCH₃)₄Cl₂, RuCl₃*xH₂O, and the like.

The concentration of the metal source compound starting material can vary over a wide range, and need only be that minimum amount necessary to react with the salt to produce the intermediate reaction material and to provide the given metal concentration desired to be employed and which will furnish the basis for at least the amount of metal necessary for the organometallic compounds of this invention. In general, depending on the size of the reaction mixture, metal source compound starting material concentrations in the range of from about 1 millimole or less to about 10,000 millimoles or greater, should be sufficient for most processes.

The salt starting material may be selected from a wide variety of compounds known in the art. Illustrative salts include lithium 2,5-dimethylpyrrolide, sodium cyclopentadienide, potassium cyclopentadienide, lithium cyclopentadienide, potassium methylboratabenzene, trimethylsilyl 2,4-dimethylpentadienide, and the like. The salt starting material is preferably sodium cyclopentadiene and the like.

The concentration of the salt starting material can vary over a wide range, and need only be that minimum amount necessary to react with the metal source compound starting material to produce an intermediate reaction material. In general, depending on the size of the first reaction mixture, salt starting material concentrations in the range of from about 1 millimole or less to about 10,000 millimoles or greater, should be sufficient for most processes.

The first solvent employed in the method of this invention may be any saturated and unsaturated hydrocarbons, aromatic hydrocarbons, aromatic heterocycles, alkyl halides, silylated hydrocarbons, ethers, polyethers, thioethers, esters, thioesters, lactones, amides, amines, polyamines, silicone oils, other aprotic solvents, or mixtures of one or more of the above; more preferably, diethylether, pentanes, or dimethoxyethanes; and most preferably tetrahydrofuran (THF), toluene or dimethoxyethane (DME) or mixtures thereof. Any suitable solvent which does not unduly adversely interfere with the intended reaction can be employed. Mixtures of one or more different solvents may be employed if desired. The amount of solvent employed is not critical to the subject invention and need only be that amount sufficient to solubilize the reaction components in the reaction mixture. In general, the amount of solvent may range from about 5 percent by weight up to about 99 percent by weight or more based on the total weight of the reaction mixture starting materials.

Reaction conditions for the reaction of the salt compound with the metal source compound to produce the intermediate reaction material, such as temperature, pressure and contact time, may also vary greatly and any suitable combination of such conditions may be employed herein. The reaction temperature may be the reflux temperature of any of the aforementioned solvents, and more preferably between about −80° C. to about 150° C., and most preferably between about 20° C. to about 120° C. Normally the reaction is carried out under ambient pressure and the contact time may vary from a matter of seconds or minutes to a few hours or greater. The reactants can be added to the reaction mixture or combined in any order. The stir time employed can range from about 0.1 to about 400 hours, preferably from about 1 to 75 hours, and more preferably from about 4 to 16 hours, for all steps.

The intermediate reaction material may be selected from a wide variety of materials known in the art. Illustrative intermediate reaction materials include (2,5-dimethylpyrrolyl)dicarbonylruthenium, (EtCp)Ru(PPh3)₂Cl, (pyrrolyl)Ru(CO)₂Cl, (methylboratabenzene)Ru(CO)₂Br, (EtCp)Ru(CO)₂Cl, and the like. The intermediate reaction material is preferably (EtCp)Ru(CO)₂Cl or (pyrrolyl)Ru(CO)₂Cl. The process of this invention does not require isolation of the intermediate reaction material.

The concentration of the intermediate reaction material can vary over a wide range, and need only be that minimum amount necessary to react with the base material to produce the organometallic compounds of this invention. In general, depending on the size of the second reaction mixture, intermediate reaction material concentrations in the range of from about 1 millimole or less to about 10,000 millimoles or greater, should be sufficient for most processes.

The alkyl source material may be selected from a wide variety of compounds known in the art. Illustrative alkyl source compounds include methyllithium, methylmagnesium bromide, ethylmagnesiumbromide, diethylcopper, and the like. Alkyl sources that would result in organometallic complexes without beta hydrogens are preferred when thermal stability is highly desirable. The alkyl source material is preferably methyllithium and the like.

The concentration of the alkyl source material can vary over a wide range, and need only be that minimum amount necessary to react with the intermediate reaction material to produce the organometallic compounds of this invention. In general, depending on the size of the first reaction mixture, alkyl source material concentrations in the range of from about 1 millimole or less to about 10,000 millimoles or greater, should be sufficient for most processes.

The second solvent employed in the method of this invention may be any saturated and unsaturated hydrocarbons, aromatic hydrocarbons, aromatic heterocycles, alkyl halides, silylated hydrocarbons, ethers, polyethers, thioethers, esters, thioesters, lactones, amides, amines, polyamines, silicone oils, other aprotic solvents, or mixtures of one or more of the above; more preferably, diethylether, pentanes, or dimethoxyethanes; and most preferably toluene, hexane or mixtures thereof. Any suitable solvent which does not unduly adversely interfere with the intended reaction can be employed. Mixtures of one or more different solvents may be employed if desired. The amount of solvent employed is not critical to the subject invention and need only be that amount sufficient to solubilize the reaction components in the reaction mixture. In general, the amount of solvent may range from about 5 percent by weight up to about 99 percent by weight or more based on the total weight of the reaction mixture starting materials.

Reaction conditions for the reaction of the intermediate reaction material with the alkyl source material to produce the organometallic precursors of this invention, such as temperature, pressure and contact time, may also vary greatly and any suitable combination of such conditions may be employed herein. The reaction temperature may be the reflux temperature of any of the aforementioned solvents, and more preferably between about −80° C. to about 150° C., and most preferably between about 20° C. to about 120° C. Normally the reaction is carried out under ambient pressure and the contact time may vary from a matter of seconds or minutes to a few hours or greater. The reactants can be added to the reaction mixture or combined in any order. The stir time employed can range from about 0.1 to about 400 hours, preferably from about 1 to 75 hours, and more preferably from about 4 to 16 hours, for all steps.

Isolation of the complex may be achieved by filtering to remove solids, reduced pressure to remove solvent, and distillation (or sublimation) to afford the final pure compound. Chromatography may also be employed as a final purification method.

This invention further relates in part to a process for producing an organometallic compound having the formula (L₁)M(L₆) wherein M is a metal or metalloid having a (+2) oxidation state, L₁ is a substituted or unsubstituted anionic 6 electron donor ligand, and L₆ is a substituted or unsubstituted anionic 4 electron donor ligand with a pendant neutral 2 electron donor moiety; which process comprises reacting a metal halide and a first salt in the presence of a first solvent and under reaction conditions sufficient to produce a first intermediate reaction material, and reacting said first intermediate reaction material with a second salt in the presence of a second solvent and under reaction conditions sufficient to produce a second intermediate reaction material, and heating said second intermediate reaction material to produce said organometallic compound. The organometallic compound yield resulting from the process of this invention can be 40% or greater, preferably 35% or greater, and more preferably 30% or greater.

The process is particularly well-suited for large scale production since it can be conducted using the same equipment, some of the same reagents and process parameters that can easily be adapted to manufacture a wide range of products. The process provides for the synthesis of organometallic precursor compounds using a process where all manipulations can be carried out in a single vessel, and which route to the organometallic precursor compounds does not require the isolation of an intermediate complex.

The metal halide compound starting material may be selected from a wide variety of compounds known in the art. The invention herein most prefers metals selected from Ru, Fe and Os. Other illustrative metals include, for example, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Hg, Al, Ga, Si, Ge, a Lanthanide series element or an Actinide series element. Illustrative metal halide compounds include, for example, [Ru(CO)₃Cl₂]₂, Ru(PPh₃)₃Cl₂, Ru(PPh₃)₄Cl₂, [Ru(C₆H₆)Cl₂]₂, Ru(NCCH₃)₄Cl₂, RuCl₃*XH₂O, and the like.

The concentration of the metal source compound starting material can vary over a wide range, and need only be that minimum amount necessary to react with the first salt to produce the first intermediate reaction material and to provide the given metal concentration desired to be employed and which will furnish the basis for at least the amount of metal necessary for the organometallic compounds of this invention. In general, depending on the size of the reaction mixture, metal source compound starting material concentrations in the range of from about 1 millimole or less to about 10,000 millimoles or greater, should be sufficient for most processes.

The first salt starting material may be selected from a wide variety of compounds known in the art. Illustrative first salts include lithium 2,5-dimethylpyrrolide, sodium cyclopentadienide, potassium cyclopentadienide, lithium cyclopentadienide, potassium methylboratabenzene, lithium 2,4-dimethylpentadienide, and the like. The first salt starting material is preferably sodium cyclopentadienide and the like.

The concentration of the first salt starting material can vary over a wide range, and need only be that minimum amount necessary to react with the metal source compound starting material to produce the first intermediate reaction material. In general, depending on the size of the first reaction mixture, salt starting material concentrations in the range of from about 1 millimole or less to about 10,000 millimoles or greater, should be sufficient for most processes.

The first solvent employed in the method of this invention may be any saturated and unsaturated hydrocarbons, aromatic hydrocarbons, aromatic heterocycles, alkyl halides, silylated hydrocarbons, ethers, polyethers, thioethers, esters, thioesters, lactones, amides, amines, polyamines, silicone oils, other aprotic solvents, or mixtures of one or more of the above; more preferably, diethylether, pentanes, or dimethoxyethanes; and most preferably tetrahydrofuran (THF), toluene or dimethoxyethane (DME) or mixtures thereof. Any suitable solvent which does not unduly adversely interfere with the intended reaction can be employed. Mixtures of one or more different solvents may be employed if desired. The amount of solvent employed is not critical to the subject invention and need only be that amount sufficient to solubilize the reaction components in the reaction mixture. In general, the amount of solvent may range from about 5 percent by weight up to about 99 percent by weight or more based on the total weight of the reaction mixture starting materials.

Reaction conditions for the reaction of the first salt compound with the metal source compound to produce the first intermediate reaction material, such as temperature, pressure and contact time, may also vary greatly and any suitable combination of such conditions may be employed herein. The reaction temperature may be the reflux temperature of any of the aforementioned solvents, and more preferably between about −80° C. to about 150° C., and most preferably between about 20° C. to about 120° C. Normally the reaction is carried out under ambient pressure and the contact time may vary from a matter of seconds or minutes to a few hours or greater. The reactants can be added to the reaction mixture or combined in any order. The stir time employed can range from about 0.1 to about 400 hours, preferably from about 1 to 75 hours, and more preferably from about 4 to 16 hours, for all steps.

The first intermediate reaction material may be selected from a wide variety of materials known in the art. Illustrative intermediate reaction materials include (2,5-dimethylpyrrolyl)dicarbonylruthenium, (EtCp)Ru(PPh3)₂Cl, (pyrrolyl)Ru(DPPE)Cl, (methylboratabenzene)Ru(CO)₂Cl, (pyrrolyl)Ru(PPh₃)₂Cl, and the like. The first intermediate reaction material is preferably (EtCp)Ru(PPh₃)₂Cl or (pyrrolyl)Ru(PPh₃)₂Cl. The process of this invention does not require isolation of the first intermediate reaction material.

The concentration of the first intermediate reaction material can vary over a wide range, and need only be that minimum amount necessary to react with the second salt starting material. In general, depending on the size of the second reaction mixture, first intermediate reaction material concentrations in the range of from about 1 millimole or less to about 10,000 millimoles or greater, should be sufficient for most processes.

The second salt starting material may be selected from a wide variety of compounds known in the art. Illustrative second salts include Na[EtNCCH₃N(CH₂)₂N(CH₃)₂], Li[H₂CCHCH(CH₂)₂N(CH₃)₂], [EtNCCH₃N(CH₂)₂(CH═CH₂)]MgBr, TMS[H₂CCHCH(CH₂)₂(HC═CH₂)], Li[EtNCCH₃N(CH₂)₂N(CH₃)₂], and the like. The second salt starting material is preferably Li[EtNCCH₃N(CH₂)₂N(CH₃)₂] and the like.

The concentration of the second salt starting material can vary over a wide range, and need only be that minimum amount necessary to react with the first intermediate reaction material to produce a second intermediate reaction material. In general, depending on the size of the first reaction mixture, salt starting material concentrations in the range of from about 1 millimole or less to about 10,000 millimoles or greater, should be sufficient for most processes.

The second solvent employed in the method of this invention may be any saturated and unsaturated hydrocarbons, aromatic hydrocarbons, aromatic heterocycles, alkyl halides, silylated hydrocarbons, ethers, polyethers, thioethers, esters, thioesters, lactones, amides, amines, polyamines, silicone oils, other aprotic solvents, or mixtures of one or more of the above; more preferably, diethylether, pentanes, or dimethoxyethanes; and most preferably toluene, hexane or mixtures thereof. Any suitable solvent which does not unduly adversely interfere with the intended reaction can be employed. Mixtures of one or more different solvents may be employed if desired. The amount of solvent employed is not critical to the subject invention and need only be that amount sufficient to solubilize the reaction components in the reaction mixture. In general, the amount of solvent may range from about 5 percent by weight up to about 99 percent by weight or more based on the total weight of the reaction mixture starting materials.

Reaction conditions for the reaction of the first intermediate reaction material with the second salt material to produce the product material, such as temperature, pressure and contact time, may also vary greatly and any suitable combination of such conditions may be employed herein. The reaction temperature may be the reflux temperature of any of the aforementioned solvents, and more preferably between about −80° C. to about 150° C., and most preferably between about 20° C. to about 120° C. Normally the reaction is carried out under ambient pressure and the contact time may vary from a matter of seconds or minutes to a few hours or greater. The reactants can be added to the reaction mixture or combined in any order. The stir time employed can range from about 0.1 to about 400 hours, preferably from about 1 to 75 hours, and more preferably from about 4 to 16 hours, for all steps.

Isolation of the complex may be achieved by filtering to remove solids, reduced pressure to remove solvent, and distillation (or sublimation) to afford the final pure compound. Chromatography may also be employed as a final purification method.

Other alternative processes that may be used in preparing the organometallic compounds of this invention include those disclosed in U.S. Pat. No. 6,605,735 B2 and U.S. Patent Application Publication No. US 2004/0127732 A1, published Jul. 1, 2004, the disclosure of which is incorporated herein by reference. The organometallic compounds of this invention may also be prepared by conventional processes such as described in Legzdins, P. et al. Inorg. Synth. 1990, 28, 196 and references therein.

For organometallic compounds prepared by the method of this invention, purification can occur through recrystallization, more preferably through extraction of reaction residue (e.g., hexane) and chromatography, and most preferably through sublimation and distillation.

Those skilled in the art will recognize that numerous changes may be made to the method described in detail herein, without departing in scope or spirit from the present invention as more particularly defined in the claims below.

Examples of techniques that can be employed to characterize the organometallic compounds formed by the synthetic methods described above include, but are not limited to, analytical gas chromatography, nuclear magnetic resonance, thermogravimetric analysis, inductively coupled plasma mass spectrometry, differential scanning calorimetry, vapor pressure and viscosity measurements.

Relative vapor pressures, or relative volatility, of organometallic precursor compounds described above can be measured by thermogravimetric analysis techniques known in the art. Equilibrium vapor pressures also can be measured, for example by evacuating all gases from a sealed vessel, after which vapors of the compounds are introduced to the vessel and the pressure is measured as known in the art.

The organometallic precursor compounds described herein are well suited for preparing in-situ powders and coatings. For instance, an organometallic precursor compound can be applied to a substrate and then heated to a temperature sufficient to decompose the precursor, thereby forming a metal coating on the substrate. Applying the precursor to the substrate can be by painting, spraying, dipping or by other techniques known in the art. Heating can be conducted in an oven, with a heat gun, by electrically heating the substrate, or by other means, as known in the art. A layered coating can be obtained by applying an organometallic precursor compound, and heating and decomposing it, thereby forming a first layer, followed by at least one other coating with the same or different precursors, and heating.

Organometallic precursor compounds such as described above also can be atomized and sprayed onto a substrate. Atomization and spraying means, such as nozzles, nebulizers and others, that can be employed are known in the art.

This invention provides in part an organometallic precursor and a method of forming a metal layer on a substrate by CVD or ALD of the organometallic precursor. In one aspect of the invention, an organometallic precursor of this invention is used to deposit a metal layer at subatmospheric pressures. The method for depositing the metal layer comprises introducing the precursor into a processing chamber, preferably maintained at a pressure of less than about 20 Torr, and dissociating the precursor in the presence of a processing gas to deposit a metal layer. The precursor may be dissociated and deposited by a thermal or plasma-enhanced process. The method may further comprise a step of exposing the deposited layer to a plasma process to remove contaminants, density the layer, and reduce the layer's resistivity.

In preferred embodiments of the invention, an organometallic compound, such as described above, is employed in gas phase deposition techniques for forming powders, films or coatings. The compound can be employed as a single source precursor or can be used together with one or more other precursors, for instance, with vapor generated by heating at least one other organometallic compound or metal complex. More than one organometallic precursor compound, such as described above, also can be employed in a given process.

As indicated above, this invention also relates in part to a method for producing a film, coating or powder. The method includes the step of decomposing an organometallic precursor compound having the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2-electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0; thereby producing the film, coating or powder, as further described below.

Deposition methods described herein can be conducted to form a film, powder or coating that includes a single metal or a film, powder or coating that includes a single metal. Mixed films, powders or coatings also can be deposited, for instance mixed metal films.

Gas phase film deposition can be conducted to form film layers of a desired thickness, for example, in the range of from about 1 nm to over 1 mm. The precursors described herein are particularly useful for producing thin films, e.g., films having a thickness in the range of from about 10 nm to about 100 nm. Films of this invention, for instance, can be considered for fabricating metal electrodes, in particular as n-channel metal electrodes in logic, as capacitor electrodes for DRAM applications, and as dielectric materials.

The method also is suited for preparing layered films, wherein at least two of the layers differ in phase or composition. Examples of layered film include metal-insulator-semiconductor, and metal-insulator-metal.

In an embodiment, the invention is directed to a method that includes the step of decomposing vapor of an organometallic precursor compound described above, thermally, chemically, photochemically or by plasma activation, thereby forming a film on a substrate. For instance, vapor generated by the compound is contacted with a substrate having a temperature sufficient to cause the organometallic compound to decompose and form a film on the substrate.

The organometallic precursor compounds can be employed in chemical vapor deposition or, more specifically, in metal organic chemical vapor deposition processes known in the art. For instance, the organometallic precursor compounds described above can be used in atmospheric, as well as in low pressure, chemical vapor deposition processes. The compounds can be employed in hot wall chemical vapor deposition, a method in which the entire reaction chamber is heated, as well as in cold or warm wall type chemical vapor deposition, a technique in which only the substrate is being heated.

The organometallic precursor compounds described above also can be used in plasma or photo-assisted chemical vapor deposition processes, in which the energy from a plasma or electromagnetic energy, respectively, is used to activate the chemical vapor deposition precursor. The compounds also can be employed in ion-beam, electron-beam assisted chemical vapor deposition processes in which, respectively, an ion beam or electron beam is directed to the substrate to supply energy for decomposing a chemical vapor deposition precursor. Laser-assisted chemical vapor deposition processes, in which laser light is directed to the substrate to affect photolytic reactions of the chemical vapor deposition precursor, also can be used.

The method of the invention can be conducted in various chemical vapor deposition reactors, such as, for instance, hot or cold-wall reactors, plasma-assisted, beam-assisted or laser-assisted reactors, as known in the art.

Examples of substrates that can be coated employing the method of the invention include solid substrates such as metal substrates, e.g., Al, Ni, Ti, Co, Pt, metal silicides, e.g., TiSi₂, CoSi₂, NiSi₂; semiconductor materials, e.g., Si, SiGe, GaAs, InP, diamond, GaN, SiC; insulators, e.g., SiO₂, Si₃N₄, HfO₂, Ta₂O₅, Al₂O₃, barium strontium titanate (BST); or on substrates that include combinations of materials. In addition, films or coatings can be formed on glass, ceramics, plastics, thermoset polymeric materials, and on other coatings or film layers. In preferred embodiments, film deposition is on a substrate used in the manufacture or processing of electronic components. In other embodiments, a substrate is employed to support a low resistivity conductor deposit that is stable in the presence of an oxidizer at high temperature or an optically transmitting film.

The method of this invention can be conducted to deposit a film on a substrate that has a smooth, flat surface. In an embodiment, the method is conducted to deposit a film on a substrate used in wafer manufacturing or processing. For instance, the method can be conducted to deposit a film on patterned substrates that include features such as trenches, holes or vias. Furthermore, the method of the invention also can be integrated with other steps in wafer manufacturing or processing, e.g., masking, etching and others.

In an embodiment of this invention, a plasma assisted ALD (PEALD) method has been developed for using the organometallic precursors to deposit metal films. The solid precursor can be sublimed under the flow of an inert gas to introduce it into a CVD chamber. Metal films are grown on a substrate with the aid of a hydrogen plasma.

Chemical vapor deposition films can be deposited to a desired thickness. For example, films formed can be less than 1 micron thick, preferably less than 500 nanometers and more preferably less than 200 nanometers thick. Films that are less than 50 nanometers thick, for instance, films that have a thickness between about 0.1 and about 20 nanometers, also can be produced.

Organometallic precursor compounds described above also can be employed in the method of the invention to form films by ALD processes or atomic layer nucleation (ALN) techniques, during which a substrate is exposed to alternate pulses of precursor, oxidizer and inert gas streams. Sequential layer deposition techniques are described, for example, in U.S. Pat. No. 6,287,965 and in U.S. Pat. No. 6,342,277. The disclosures of both patents are incorporated herein by reference in their entirety.

For example, in one ALD cycle, a substrate is exposed, in step-wise manner, to: a) an inert gas; b) inert gas carrying precursor vapor; c) inert gas; and d) oxidizer, alone or together with inert gas. In general, each step can be as short as the equipment will permit (e.g. milliseconds) and as long as the process requires (e.g. several seconds or minutes). The duration of one cycle can be as short as milliseconds and as long as minutes. The cycle is repeated over a period that can range from a few minutes to hours. Film produced can be a few nanometers thin or thicker, e.g., 1 millimeter (mm).

This invention includes a method for forming a metal-containing material on a substrate, e.g., a microelectronic device structure, from an organometallic precursor of this invention, said method comprising vaporizing said organometallic precursor to form a vapor, and contacting the vapor with the substrate to form said metal material thereon. After the metal is deposited on the substrate, the substrate may thereafter be metallized with copper or integrated with a ferroelectric thin film.

In an embodiment of this invention, a method is provided for fabricating a microelectronic device structure, said method comprising vaporizing an organometallic precursor compound to form a vapor, and contacting said vapor with a substrate to deposit a metal-containing film on the substrate, and thereafter incorporating the metal-containing film into a semiconductor integration scheme; wherein said organometallic precursor compound is represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0.

The method of the invention also can be conducted using supercritical fluids. Examples of film deposition methods that use supercritical fluid that are currently known in the art include chemical fluid deposition; supercritical fluid transport-chemical deposition; supercritical fluid chemical deposition; and supercritical immersion deposition.

Chemical fluid deposition processes, for example, are well suited for producing high purity films and for covering complex surfaces and filling of high-aspect-ratio features. Chemical fluid deposition is described, for instance, in U.S. Pat. No. 5,789,027. The use of supercritical fluids to form films also is described in U.S. Pat. No. 6,541,278 B2. The disclosures of these two patents are incorporated herein by reference in their entirety.

In an embodiment of the invention, a heated patterned substrate is exposed to one or more organometallic precursor compounds, in the presence of a solvent, such as a near critical or supercritical fluid, e.g., near critical or supercritical CO₂. In the case of CO₂, the solvent fluid is provided at a pressure above about 1000 psig and a temperature of at least about 30° C.

The precursor is decomposed to form a metal film on the substrate. The reaction also generates organic material from the precursor. The organic material is solubilized by the solvent fluid and easily removed away from the substrate.

In an example, the deposition process is conducted in a reaction chamber that houses one or more substrates. The substrates are heated to the desired temperature by heating the entire chamber, for instance, by means of a furnace. Vapor of the organometallic compound can be produced, for example, by applying a vacuum to the chamber. For low boiling compounds, the chamber can be hot enough to cause vaporization of the compound. As the vapor contacts the heated substrate surface, it decomposes and forms a metal film. As described above, an organometallic precursor compound can be used alone or in combination with one or more components, such as, for example, other organometallic precursors, inert carrier gases or reactive gases.

In an embodiment of this invention, a method is provided for forming a metal-containing material on a substrate from an organometallic precursor compound, said method comprising vaporizing said organometallic precursor compound to form a vapor, and contacting the vapor with the substrate to form said metal material thereon; wherein said organometallic precursor compound is represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0.

In another embodiment of this invention, a method is provided for processing a substrate in a processing chamber, said method comprising (i) introducing an organometallic precursor compound into said processing chamber, (ii) heating said substrate to a temperature of about 100° C. to about 400° C., and (iii) dissociating said organometallic precursor compound in the presence of a processing gas to deposit a metal layer on said substrate; wherein said organometallic precursor compound is represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0.

In a system that can be used in producing films by the method of the invention, raw materials can be directed to a gas-blending manifold to produce process gas that is supplied to a deposition reactor, where film growth is conducted. Raw materials include, but are not limited to, carrier gases, reactive gases, purge gases, precursor, etch/clean gases, and others. Precise control of the process gas composition is accomplished using mass-flow controllers, valves, pressure transducers, and other means, as known in the art. An exhaust manifold can convey gas exiting the deposition reactor, as well as a bypass stream, to a vacuum pump. An abatement system, downstream of the vacuum pump, can be used to remove any hazardous materials from the exhaust gas. The deposition system can be equipped with in-situ analysis system, including a residual gas analyzer, which permits measurement of the process gas composition. A control and data acquisition system can monitor the various process parameters (e.g., temperature, pressure, flow rate, etc.).

The organometallic precursor compounds described above can be employed to produce films that include a single metal or a film that includes a single metal. Mixed films also can be deposited, for instance mixed metal films. Such films are produced, for example, by employing several organometallic precursors. Metal films also can be formed, for example, by using no carrier gas, vapor or other sources of oxygen.

Films formed by the methods described herein can be characterized by techniques known in the art, for instance, by X-ray diffraction, Auger spectroscopy, X-ray photoelectron emission spectroscopy, atomic force microscopy, scanning electron microscopy, and other techniques known in the art. Resistivity and thermal stability of the films also can be measured, by methods known in the art.

In addition to their use in semiconductor applications as chemical vapor or atomic layer deposition precursors for film depositions, the organometallic compounds of this invention may also be useful, for example, as catalysts, fuel additives and in organic syntheses.

Various modifications and variations of this invention will be obvious to a worker skilled in the art and it is to be understood that such modifications and variations are to be included within the purview of this application and the spirit and scope of the claims.

### Example 1

### Synthesis of (MeCp)(1,5-hexadiene)Ru

A 100 milliliter, 3-necked round-bottomed flask equipped with a Teflon stir bar was fitted with a condenser, a glass stopper and a rubber septum. A stopcock adapter was connected to the top of the condenser and the entire system was connected to an inert atmosphere/vacuum manifold.

Under a nitrogen purge, one glass stopper was removed and the flask was charged with (MeCp)Ru(PPh₃)₂Cl (15.0 grams, 0.02 mol). THF (anhydrous, 30 milliliters) and ethanol (30 milliliters) were added to the 100 milliliter flask via a cannula through the rubber septum and the solution was stirred.

Zinc (10 grams, excess) was then added to the flask and the contents were permitted to stir for 30 minutes. A solution of 1,5-hexadiene in THF was prepared in a 20 milliliter flask in an inert atmosphere glovebox. The contents of this flask were then cannulated into the 100 milliliter round-bottomed flask.

The reaction was heated to reflux overnight while stirring continued. GC-MS revealed peaks consistent with (MeCp)(1,5-hexadiene)Ru with a strong peak at 262 Da/e⁻ and appropriate isotope distribution characteristic of the desired product.

The entire contents of the flask were evacuated under vacuum and the remaining mass was dissolved in methanol (50 milliliter). Hexanes (50 milliliter) were used to extract the (MeCp)(1,5-hexadiene)Ru product from the methanol solution. Hexanes were removed to isolate a crude (MeCp)(1,5-hexadiene)Ru. Subsequent purification to isolate a pure product may be carried out by chromatography or sublimation.

### Example 2

### Synthesis of CpRu(Allyl)CO

These compounds were synthesized in the manner reported in Journal of Gibson, et. al., Journal of Organometallic Chemistry, 208 (1981) 89-102.

In a 200 milliliter flask benzyltriethylammonium chloride (3.4 grams, 15 mmol) and a solution of NaOH (5N, 100 milliliters) was added. A second 500 milliliter flask was prepared by adding a CH₂Cl₂ (100 milliliters), allyl bromide (1.3 milliliters, 15 mmol), CpRu(CO)₂Br (1.5 grams, 5 mmol) and a Teflon stir bar. The caustic aqueous solution was added rapidly and the solution was stirred during the addition. The solution was stirred for 15 minutes following the addition.

The heterogeneous solution was transferred to a separation flask and the dichloromethane product containing layer was removed. The aqueous layer was discarded. CH₂Cl₂ solvent removal under reduced pressure afforded a brownish-yellow residue. This residue was extracted using hexane (4 times 50 milliliters) and dried using MgSO₄ then filtered. Solvent was again removed under reduced pressure and a yellow solid was afforded.

Subsequent sublimation of this material yielded a mixture of endo and exo isomers of CpRu(CO)allyl (0.3 grams, 30% yield—literature reports that higher yields may be anticipated).

### Example 3

### Thermogravimetric Analysis of CpRu(CO)Allyl

Thermogravimetric analyses of CpRu(CO)allyl reveal that it exhibits acceptable vapor pressure characteristics for use as a precursor. However, it also demonstrates that there are two volatile components. Based on the ¹H NMR analysis these have been tentatively ascribed as the endo and exo isomers. Mixtures of both isomers or purified individual isomers (which may be afforded by purification or conversion of one isomer to the other by methods established in the literature) may likely thus be used as CVD precursor.

### Example 4

### Plasma Enhanced Atomic Layer Deposition (PEALD) of CpRu(CO)Allyl

CpRu(CO)allyl was charged into a flow cell vaporizer. The flow cell vaporizer was heated to 50° C. and 100 standard cubic centimeters per minute Ar was passed over the cell to entrain vapors. A pulsed deposition experiment was conducted that involved a pulse sequence of 20 seconds precursor stream dosage, 40 second purge, 20 seconds of hydrogen plasma (15 W load @20 W forward power) and another 40 second purge.

Two substrates were employed in the experiment: (a) TaN, and (b) SiO₂. The temperature of the substrates was indirectly measured by recording the temperature of the backside of the susceptor on which the coupons were placed. The backside susceptor was heated to 450° C.

Following the experiment there was visual evidence of films on both substrates. This was different from results in which no plasmas was used. Passing the precursor over the substrate either in the absence of a reactant gas or in the presence of molecular hydrogen resulted in no deposition at a backside susceptor temperature of 450° C.

1. A method for producing a film, coating or powder by decomposing an organometallic precursor compound having the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0; thereby producing said film, coating or powder.

2. The method of claim 1 wherein the decomposing of said organometallic precursor compound is thermal, chemical, photochemical or plasma-activated.

3. The method of claim 1 wherein said organometallic precursor compound is vaporized and the vapor is directed into a deposition reactor housing a substrate.

4. The method of claim 3 wherein said substrate is comprised of a material selected from the group consisting of a metal, a metal silicide, a semiconductor, an insulator and a barrier material.

5. The method of claim 3 wherein said substrate is a patterned wafer.

6. The method of claim 1 wherein said film, coating or powder is produced by a gas phase deposition.

7. The method of claim 3 wherein a metal layer is deposited on said substrate by plasma assisted chemical vapor deposition or plasma assisted atomic layer deposition.

8. The method of claim 1 wherein, for said organometallic precursor compound, M is selected from ruthenium (Ru), iron (Fe) and osmium (Os), L₁ is selected from a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, a substituted or unsubstituted pyrazolyl-like group, a substituted or unsubstituted boratabenzene group, and a substituted or unsubstituted boratabenzene-like group, and L₂ is selected from (i) a substituted or unsubstituted hydrido, halo and an alkyl group having from 1 to 12 carbon atoms, (ii) a substituted or unsubstituted allyl, azaallyl, amidinate and betadiketiminate group, (iii) a substituted or unsubstituted carbonyl, phosphino, amino, alkenyl, alkynyl, nitrile and isonitrile group, and (iv) a substituted or unsubstituted anionic 4 electron donor ligand with a pendant neutral 2 electron donor moiety; wherein the substituted or unsubstituted cyclopentadienyl-like group is selected from cyclohexadienyl, cycloheptadienyl, cyclooctadienyl, heterocyclic group and aromatic group, the substituted or unsubstituted cycloheptadienyl-like group is selected from cyclohexadienyl, cyclooctadienyl, heterocyclic group and aromatic group, the substituted or unsubstituted pentadienyl-like group is selected from linear olefins, hexadienyl, heptadienyl and octadienyl, the substituted or unsubstituted pyrrolyl-like group is selected from pyrrolinyl, pyrazolyl, thiazolyl, oxazolyl, carbazolyl, triazolyl, indolyl and purinyl, the substituted or unsubstituted imidazoyl-like group is selected from pyrrolinyl, pyrazolyl, thiazolyl, oxazolyl, carbazolyl, triazolyl, indolyl and purinyl, the substituted or unsubstituted pyrazolyl-like group is selected from pyrrolinyl, pyrazolyl, thiazolyl, oxazolyl, carbazolyl, triazolyl, indolyl and purinyl, and the substituted or unsubstituted boratabenzyl-like group is selected from methylboratabenzene, ethylboratabenzene, 1-methyl-3-ethylboratabenzene or other functionalized boratabenzene moieties.

9. The method of claim 1 wherein said organometallic precursor compound is selected from methylboratabenzene(allyl)carbonylruthenium(II), (pyrrolyl)trimethylamino(diisopropylacetamidinato)ruthenium(II), (ethylcyclopentadienyl)allyl(carbonyl)ruthenium(II), cyclopentadienyl(2-methyl-allyl)carbonylruthenium(II), (ethylcyclopentadienyl)(dimethyl)allylruthenium(IV), (2,5-dimethylpyrrolyl)(dimethyl)allylruthenium(IV), allyl(ethylcyclopentadienyl)dimethylruthenium(IV), (methylboratabenzene)dimethyl(diisopropylacetamidinato)ruthenium(IV), (ethylcyclopentadienyl)dicarbonyl(methyl)ruthenium(II), pyrrolyl(dicarbonyl)(methyl)ruthenium(II), methylboratabenzene-di(trimethylphosphino)methylruthenium(II), [ⁱPrNCCH₃N(CH₂)₃N(CH₃)₂](ethylcyclopentadienyl)ruthenium(II), [EtNCCH₃N(CH₂)₂N(CH₃)₂] (cyclopentadienyl)ruthenium(II), [H₂CCHCH(CH₂)₃N(CH₃)₂] (ethylcyclopentadienyl)ruthenium(II), [H₂CCHCH(CH₂)₂(HC═CH₂)](pyrrolyl)ruthenium(II), [ⁱPrNCCH₃N(CH₂)₃N(CH₃)₂](methylboratabenzene)ruthenium(II), methylboratabenzene(allyl)carbonylosmium(II), (pyrrolyl)trimethylamino(diisopropylacetamidinato)iron(II), (ethylcyclopentadienyl)allyl(carbonyl)osmium(II), cyclopentadienyl(2-methyl-allyl)carbonyliron(II), allyl(carbonyl)ethylcyclopentadienyliron(II), (ethylcyclopentadienyl)(dimethyl)allylosmium(IV), (2,5-dimethylpyrrolyl) (dimethyl)allyliron(IV), (methylboratabenzene)dimethyl(diisopropyl-acetamidinato)osmium(IV), allyl(ethylcyclopentadienyl)dimethylosmium(IV), (pyrrolyl)methyl(dicarbonyl)iron(II), (ethylcyclopentadienyl)dicarbonyl(methyl)iron(II), pyrrolyl(dicarbonyl)(methyl)osmium(II), methylboratabenzene-di(trimethylphosphino)methyliron(II), [ⁱPrNCCH₃N(CH₂)₃N(CH₃)₂](ethylcyclopentadienyl)osmium(II), [ⁱPrNCCH₃N(CH₂)₃N(CH₃)₂](methylboratabenzene)osmium(II), [ⁱPrNCCH₃N(CH₂)₃N(CH₃)₂](ethylcyclopentadienyl)iron(II), [EtNCCH₃N(CH₂)₂N(CH₃)₂] (cyclopentadienyl)osmium(II), [H₂CCHCH(CH₂)₃N(CH₃)₂](ethylcyclopentadienyl)osmium(II), and [H₂CCHCH(CH₂)₂(HC═CH₂)](pyrrolyl)iron(II).

10. A method for processing a substrate in a processing chamber, said method comprising (i) introducing an organometallic precursor compound into said processing chamber, (ii) heating said substrate to a temperature of about 100° C. to about 400° C., and (iii) dissociating said organometallic precursor compound in the presence of a processing gas to deposit a metal-containing layer on said substrate; wherein said organometallic precursor compound is represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0.

11. The method of claim 10 wherein said metal-containing layer is deposited on said substrate by chemical vapor deposition or atomic layer deposition.

12. The method of claim 10 wherein said metal-containing layer is deposited on said substrate by plasma assisted chemical vapor deposition or plasma assisted atomic layer deposition.

13. The method of claim 10 wherein said processing gas is selected from hydrogen, argon, helium, or combinations thereof.

14. The method of claim 10 wherein dissociating said organometallic precursor compound further comprises generating a plasma at a power density between about 0.6 Watts/cm² and about 3.2 Watts/cm².

15. The method of claim 10 further comprising exposing the deposited metal-containing layer to a plasma generated at a power density between about 0.6 Watts/cm² and about 3.2 Watts/cm².

16. The method of claim 10 furthering comprising depositing a second metal-containing layer on the metal-containing layer.

17. The method of claim 16 wherein the second metal-containing layer comprises copper and is deposited by an electroplating technique.

18. The method of claim 10 wherein, for said organometallic precursor compound, M is selected from ruthenium (Ru), iron (Fe) and osmium (Os), L₁ is selected from a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, a substituted or unsubstituted pyrazolyl-like group, a substituted or unsubstituted boratabenzene group, and a substituted or unsubstituted boratabenzene-like group, and L₂ is selected from (i) a substituted or unsubstituted hydrido, halo and an alkyl group having from 1 to 12 carbon atoms, (ii) a substituted or unsubstituted allyl, azaallyl, amidinate and betadiketiminate group, (iii) a substituted or unsubstituted carbonyl, phosphino, amino, alkenyl, alkynyl, nitrile and isonitrile group, and (iv) a substituted or unsubstituted anionic 4 electron donor ligand with a pendant neutral 2 electron donor moiety; wherein the substituted or unsubstituted cyclopentadienyl-like group is selected from cyclohexadienyl, cycloheptadienyl, cyclooctadienyl, heterocyclic group and aromatic group, the substituted or unsubstituted cycloheptadienyl-like group is selected from cyclohexadienyl, cyclooctadienyl, heterocyclic group and aromatic group, the substituted or unsubstituted pentadienyl-like group is selected from linear olefins, hexadienyl, heptadienyl and octadienyl, the substituted or unsubstituted pyrrolyl-like group is selected from pyrrolinyl, pyrazolyl, thiazolyl, oxazolyl, carbazolyl, triazolyl, indolyl and purinyl, the substituted or unsubstituted imidazoyl-like group is selected from pyrrolinyl, pyrazolyl, thiazolyl, oxazolyl, carbazolyl, triazolyl, indolyl and purinyl, the substituted or unsubstituted pyrazolyl-like group is selected from pyrrolinyl, pyrazolyl, thiazolyl, oxazolyl, carbazolyl, triazolyl, indolyl and purinyl, and the substituted or unsubstituted boratabenzene-like group is selected from methylboratabenzene, ethylboratabenzene, 1-methyl-3-ethylboratabenzene or other functionalized boratabenzene moieties.

19. The method of claim 10 wherein said organometallic precursor compound is selected from methylboratabenzene(allyl)carbonylruthenium(II), (pyrrolyl)trimethylamino(diisopropylacetamidinato)ruthenium(II), (ethylcyclopentadienyl)allyl(carbonyl)ruthenium(II), cyclopentadienyl(2-methyl-allyl)carbonylruthenium(II), (ethylcyclopentadienyl)(dimethyl)allylruthenium(IV), (2,5-dimethylpyrrolyl)(dimethyl)allylruthenium(IV), allyl(ethylcyclopentadienyl)dimethylruthenium(IV), (methylboratabenzene)dimethyl(diisopropylacetamidinato)ruthenium(IV), (ethylcyclopentadienyl)dicarbonyl(methyl)ruthenium(II), pyrrolyl(dicarbonyl)(methyl)ruthenium(II), methylboratabenzene-di(trimethylphosphino)methylruthenium(II), [ⁱPrNCCH₃N(CH₂)₃N(CH₃)₂](ethylcyclopentadienyl)ruthenium(II), [EtNCCH₃N(CH₂)₂N(CH₃)₂] (cyclopentadienyl)ruthenium(II), [H₂CCHCH(CH₂)₃N(CH₃)₂] (ethylcyclopentadienyl)ruthenium(II), [H₂CCHCH(CH₂)₂(HC═CH₂)](pyrrolyl)ruthenium(II), [ⁱPrNCCH₃N(CH₂)₃N(CH₃)₂](methylboratabenzene)ruthenium(II), methylboratabenzene(allyl)carbonylosmium(II), (pyrrolyl)trimethylamino(diisopropylacetamidinato)iron(II), (ethylcyclopentadienyl)allyl(carbonyl)osmium(II), cyclopentadienyl(2-methyl-allyl)carbonyliron(II), allyl(carbonyl)ethylcyclopentadienyliron(II), (ethylcyclopentadienyl)(dimethyl)allylosmium(IV), (2,5-dimethylpyrrolyl) (dimethyl)allyliron(IV), (methylboratabenzene)dimethyl(diisopropyl-acetamidinato)osmium(IV), allyl(ethylcyclopentadienyl)dimethylosmium(IV), (pyrrolyl)methyl(dicarbonyl)iron(II), (ethylcyclopentadienyl)dicarbonyl(methyl)iron(II), pyrrolyl(dicarbonyl)(methyl)osmium(II), methylboratabenzene-di(trimethylphosphino)methyliron(II), [ⁱPrNCCH₃N(CH₂)₃N(CH₃)₂](ethylcyclopentadienyl)osmium(II), [ⁱPrNCCH₃N(CH₂)₃N(CH₃)₂](methylboratabenzene)osmium(II), [ⁱPrNCCH₃N(CH₂)₃N(CH₃)₂](ethylcyclopentadienyl)iron(II), [EtNCCH₃N(CH₂)₂N(CH₃)₂](cyclopentadienyl)osmium(II), [H₂CCHCH(CH₂)₃N(CH₃)₂](ethylcyclopentadienyl)osmium(II), and [H₂CCHCH(CH₂)₂(HC═CH₂)](pyrrolyl)iron(II).

20. A method for forming a metal-containing material on a substrate from an organometallic precursor compound, said method comprising vaporizing said organometallic precursor compound to form a vapor, and contacting the vapor with the substrate to form said metal material thereon; wherein said organometallic precursor compound is represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0.

21. The method of claim 20 wherein said organometallic precursor compound is deposited on said substrate, and the substrate is thereafter metallized with copper or integrated with a ferroelectric thin film.

22. A method of fabricating a microelectronic device structure, said method comprising vaporizing an organometallic precursor compound to form a vapor, and contacting said vapor with a substrate to deposit a metal-containing film on the substrate, and thereafter incorporating the metal-containing film into a semiconductor integration scheme; wherein said organometallic precursor compound represented by the formula (L₁)M(L₂)_{y} wherein M is a metal or metalloid, L₁ is a substituted or unsubstituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 4 electron donor ligand with a pendant neutral 2 electron donor moiety; and y is an integer of from 1 to 3; and wherein the sum of the oxidation number of M and the electric charges of L₁ and L₂ is equal to 0.
